(19) United States
(12) Patent Application Publication
(10) Pub. No.: US 2005/0166123 A1
(43) Pub. Date: Jul. 28, 2005

(54) Transmission/reception system, transmitter and transmitting and method, receiver and receiving method, recording medium, and program

(75) Inventors: Kaoru Yanamoto, Kanagawa (JP); Makoto Noda, Tokyo (JP); Keitarou Kondou, Tokyo (JP); Masashi Shinagawa, Tokyo (JP); Takatsuna Sasaki, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: SONY CORPORATION, Tokyo (JP)

(21) Appl. No.: 11/017,943

(22) Filed: Dec. 22, 2004

(30) Foreign Application Priority Data
Jan. 20, 2004 (JP) 2004-012177

(51) Int. Cl. H04L 1/18; H03M 13/00

(52) U.S. Cl. 714/776

(57) ABSTRACT

A transmission/reception system is provided. In a transmitter, error correction data is added to each set of N TS packets, an RTP packet is generated by collecting M (N>M) TS packets with the added error correction data and sequentially assigning a sequence number to each set of the M TS packets, and each RTP packet is transmitted by converting the RTP packets into data transmittable to a receiver. In the receiver, the data from the transmitter is received, the RTP packet is acquired from the data received, it is judged, from the sequence number of the RTP packet, whether there is any dropped packet not received, and the dropped packet is corrected by using the RTP packets, if there is a dropped packet not received.

### CROSS REFERENCES TO RELATED APPLICATIONS

The present invention contains subject matter related to Japanese Patent Application JP 2004-012177 filed in the Japanese Patent Office on Jan. 20, 2004, the entire contents of which being incorporated herein by reference.

### BACKGROUND OF THE INVENTION

1. Field of the Invention

The present invention relates to a transmission/reception system, a transmitter and a transmitting method, a receiver and a receiving method, a recording medium and a program, and more particularly to a transmission/reception system, a transmitter and a transmitting method, a receiver and a receiving method, a recording medium and a program, in which if a packet is dropped during transmission/reception, the dropped packet can be compensated easily.

2. Description of the Related Art

RTP (Real-time Transport Protocol)/UDP(User Datagram Protocol) or the like has been used conventionally as a protocol for real time AV data transmission/reception among apparatuses connected to a wired Ethernet® or a wireless network.

FIG. 1 shows an example of the configuration of a transmission/reception system of related art. In the example shown in FIG. 1, a transmission data generator unit 11 of a transmitter 1 receives an AV (Audio Video) signal of an MPEG-TS (Motion Picture Experts Group-Transport Stream) stream of a broadcast signal received via an antenna (not shown in the figure), and adds an RTP header to a predetermined number of collected MPEG-TS packets of the AV signal to generate an RTP packet. The transmission data generator unit 11 packetizes the generated RTP packet to a UDP (User Datagram Protocol) packet for real time AV data transmission, further packetizes it to an IP (Internet Protocol) packet, framizes it to a MAC (Media Access Control) frame by adding a MAC header in conformity with, for example, IEEE802.11, and outputs it to a wireless transmitter module 12. The wireless transmitter module 12 transmits the MAC framed packet supplied from the transmission data generator unit 11 to a receiver 2 via wireless communications.

A wireless receiver module 21 of the receiver 2 receives the MAC framed packet transmitted from the transmitter 1 and supplies it to a TS streamer unit 22. The TS streamer unit 22 extracts an MPEG-TS stream from the supplied MAC framed packet and loads it in an buffer (not shown in the figure). A MPEG decoder unit 23 decodes the MPEG-TS stream loaded in the buffer of the TS streamer unit 22 to reproduce an analog AV signal and display it on an display (not shown in the figure).

The transmission/reception system of related art transmits/receives data by using UDP in the manner described above. However, the transmission/reception system of related art is associated with a problem (packet drop) inherent to the characteristics of transmission/reception through UDP that some packets are dropped from a communication line and cannot be received on a receiver side.

There is a transmission/reception system capable of solving this problem in which a transmitter stores data for a predetermined time after transmission, and if a receiver requests for a dropped packet, the transmitter transmits the requested packet in the stored data.

There is another transmission/reception system (e.g., refer to U.S. Pat. No. 6,141,788) in which an FEC (Forward Error Correction) packet for transmission error correction is newly defined, and an FEC packet is added to the whole MAC frame and transmitted before a MAC framed packet is transmitted from a transmitter to thereby correct a packet dropped from a communication line, on a receiver side.

However, the former transmission/reception system requires sophisticated communications between apparatuses in addition to AV data transmission/reception, and data (packet) is required to be stored for a predetermined time after transmission on a transmitter side, resulting in a large load on the system (CPU).

In the latter transmission/reception system, since the FEC packet is newly defined, it is necessary for both a transmitter and a receiver to know in advance the error correction method or to know each other by using another method such as an RTSP (Real Time Streaming Protocol).

As described above, in order to deal with a packet drop during UDP transmission/reception, a system (transmitter and receiver) is required to be configured to have a high performance function or another function such as RTSP. The transmission/reception system of this type cannot be configured easily. Namely, in UDP transmission/reception, there is an issue that it is difficult to correct a dropped packet easily.

The present invention has been made in view of these circumstances described above, and makes it easy to correct such a packet dropped from a communication line.

### SUMMARY OF THE INVENTION

In a transmission/reception system according to an embodiment of the present invention, a transmitter includes error correction adding means for adding error correction data to each set of N TS (Transport Stream) packets, RTP (Real-time Transport Protocol) packet generating means for generating an RTP packet by collecting M (N>M) TS packets added with the error correction data by the error correction adding means and sequentially assigning a sequence number to each set of M TS packets, and transmitter means for transmitting each RTP packet generated by the RTP packet by converting the RTP packets into data transmittable to a receiver. The receiver includes receiver means for receiving the data from the transmitter, packet acquiring means for acquiring the RTP packet from the data received by the receiver means, packet judging means for judging, from the sequence number of the RTP packet acquired by the packet acquiring means, whether there is any dropped packet not received by the receiver means, and packet correcting means for correcting the dropped packet by using the RTP packets acquired by the packet acquiring means, if the packet judging means judges that there is a dropped packet not received.

The transmitter may further include interleaver means for rearranging an order of the RTP packets generated by the RTP packet generating means to a predetermined order, before the RTP packets are transmitted by the transmitter means. The receiver may further include deinterleaver means for rearranging the order of the RTP packets acquired by the packet acquiring means to an original order before being rearranged to the predetermined order by the interleaver means.

A transmitter according to an embodiment of the present invention includes error correction adding means for adding error correction data to each set of N TS (Transport Stream) packets, RTP (Real-time Transport Protocol) packet generating means for generating an RTP packet by collecting M (N>M) TS packets added with the error correction data by the error correction adding means and sequentially assigning a sequence number to each set of M TS packets, and transmitter means for transmitting each RTP packet generated by the RTP packet generating means by converting the RTP packets into data transmittable to a receiver.

The transmitter may further include interleaver means for rearranging an order of the RTP packets generated by the RTP packet generating means to a predetermined order, before the RTP packets are transmitted by the transmitter means.

A transmitting method according to an embodiment of the present invention includes an error correction adding step of adding error correction data to each set of NTS (Transport Stream) packets, an RTP (Real-time Transport Protocol) packet generating step of generating an RTP by collecting M (N>M) TS packets added with the error correction data by the error correction adding step and sequentially assigning a sequence number to each set of M TS packets, and a transmitting step of transmitting each RTP packet generated by the RTP packet generating step by converting the RTP packets into data transmittable to a receiver.

A recording medium recording a first program according to an embodiment of the present invention includes an error correction adding step of adding error correction data to each set of N TS (Transport Stream) packets, an RTP (Real-time Transport Protocol) packet generating step of generating an RTP packet by collecting M (N>M) TS packets added with the error correction data by the error correction adding step and sequentially assigning a sequence number to each set of M TS packets, and a transmitting step of transmitting each RTP packet generated by the RTP packet generating step by converting the RTP packets into data transmittable to a receiver.

A first program according to an embodiment of the present invention includes an error correction adding step of adding error correction data to each set of N TS (Transport Stream) packets, an RTP (Real-time Transport Protocol) packet generating step of generating an RTP packet by collecting M (N>M) TS packets added with the error correction data by the error correction adding step and sequentially assigning a sequence number to each set of M TS packets, and a transmitting step of transmitting each RTP packet generated by the RTP packet generating step by converting the RTP packets into data transmittable to a receiver.

A receiver according to an embodiment of the present invention includes receiver means for receiving data from a transmitter, the data including an RTP (Real-time Transport Protocol) packet generated by collecting M TS packets added with the error correction data for N (N>M) TS (Transport Stream) packets and sequentially assigning a sequence number to each set of M TS packets, packet acquiring means for acquiring the RTP packet from the data received by the receiver means, packet judging means for judging, from the sequence number of the RTP packet acquired by the packet acquiring means, whether there is any dropped packet not received by the receiver means, and packet correcting means for correcting the dropped packet by using the RTP packets acquired by the packet acquiring means, if the packet judging means judges that there is a dropped packet not received.

The receiver may further include deinterleaver means wherein the RTP packets in the data received by the receiver means were rearranged to a predetermined order by the transmitter, the deinterleaver means rearranges the order of the RTP packets acquired by the packet acquiring means to an original order before being rearranged to the predetermined order by the transmitter.

A receiving method according to an embodiment of the present invention includes a receiving step of receiving data from a transmitter, the data including an RTP (Real-time Transport Protocol) packet generated by collecting M TS packets added with the error correction data for N (N>M) TS (Transport Stream) packets and sequentially assigning a sequence number to each set of M TS packets, a packet acquiring step of acquiring the RTP packet from the data received by the receiving step, a packet judging step of judging, from the sequence number of the RTP packet acquired by the packet acquiring step, whether there is any dropped packet not received by the receiver step, and a packet correcting step of correcting the dropped packet by using the RTP packets acquired by the packet acquiring step, if the packet judging step judges that there is a dropped packet not received.

A recording medium recording a second program according to an embodiment of the present invention includes a receiving step of receiving data from a transmitter, the data including an RTP (Real-time Transport Protocol) packet generated by collecting M TS packets added with the error correction data for N (N>M) TS (Transport Stream) packets and sequentially assigning a sequence number to each set of M TS packets, a packet acquiring step of acquiring the RTP packet from the data received by the receiving step, a packet judging step of judging, from the sequence number of the RTP packet acquired by the packet acquiring step, whether there is any dropped packet not received by the receiver step, and a packet correcting step of correcting the dropped packet by using the RTP packets acquired by the packet acquiring step, if the packet judging step judges that there is a dropped packet not received.

A second program according to an embodiment of the present invention includes a receiving step of receiving data from a transmitter, the data including an RTP (Real-time Transport Protocol) packet generated by collecting M TS packets added with the error correction data for N (N>M) TS (Transport Stream) packets and sequentially assigning a sequence number to each set of M TS packets, a packet acquiring step of acquiring the RTP packet from the data received by the receiving step, a packet judging step of judging, from the sequence number of the RTP packet acquired by the packet acquiring step, whether there is any dropped packet not received by the receiver step, and a packet correcting step of correcting the dropped packet by using the RTP packets acquired by the packet acquiring step, if the packet judging step judges that there is a dropped packet not received.

In the first embodiment of the present invention, the transmitter generates the RTP (Real-time Transport Protocol) packet by adding error correction data to each set of N TS (Transport Stream) packets, collecting M (N>M) TS packets added with the error correction data, and sequentially assigning a sequence number to each set of M TS packets. The generated RTP packet is converted into data transmittable to the receiver and transmitted. The receiver receives the data from the transmitter, and the RTP packet is acquired from the received data. If it is judged from the sequence number of the acquired RTP packet that there is a dropped packet not received, the dropped packet is corrected by using the acquired RTP packets.

In the second embodiment of the present invention, the RTP packet is generated by adding error correction data to each set of N TS (Transport Stream) packets, collecting M (N>M) TS packets added with the error correction data, and sequentially assigning a sequence number to each set of M TS packets. The generated RTP packet is converted into data transmittable to the receiver and transmitted.

In the third embodiment of the present invention, data is received from the transmitter, the data including an RTP (Real-time Transport Protocol) packet generated by collecting M TS packets added with the error correction data for N (N>M) TS (Transport Stream) packets and sequentially assigning a sequence number to each set of M TS packets. The RTP packet is acquired from the received data. If it is judged from the sequence number of the acquired RTP packet that there is a dropped packet not received, the dropped packet is corrected by using the acquired RTP packets.

Transmission/reception may obviously include wireless communications and wired communications, and may be communications mixing wireless communications and wired communications, i.e., wireless communications in one section and wired communications in another section. Communications from one apparatus to another apparatus may be wired communications and communications from the other apparatus to the apparatus may be wireless communications.

### BRIEF DESCRIPTION OF THE DRAWINGS

The above and other objects, features and advantages of the present invention will become more apparent from the following description of the presently exemplary embodiment of the invention taken in conjunction with the accompanying drawings, in which:

FIG. 1 is a diagram showing an example of the configuration of a transmission/reception system of related art;

FIG. 2 is a diagram showing an example of the configuration of a transmission/reception system according to an embodiment of the present invention;

FIG. 3 is a block diagram showing an example of the structures of a transmitter unit and a receiver unit shown in FIG. 2;

FIG. 4 is a diagram showing an example of the structure of a MAC packet;

FIG. 5 is a diagram showing the data structure of an RTP header in the RTP layer;

FIG. 6 is a diagram showing an example of the structure of general RTP packets;

FIG. 7 is a diagram showing an example of the structure of an RTP packet added with error correction parity data;

FIG. 8 is a flow chart illustrating a packet transmission process by the transmitter unit shown in FIG. 2;

FIG. 9 is a flow chart illustrating a packet reception process by the receiver unit shown in FIG. 2;

FIG. 10 is a diagram showing a graph illustrating a packet drop state if communication conditions are good;

FIG. 11 is a diagram showing a graph illustrating a packet drop state if communication conditions are bad;

FIG. 12 is a diagram showing another example of the configuration of a reception/transmission system according to an embodiment of the present invention;

FIG. 13 is a block diagram showing an example of the structures of a transmitter unit and a receiver unit shown in FIG. 12;

FIG. 14 is a diagram showing another example of the structure of RTP packets added with error correction parity data;

FIG. 15 is a diagram showing an example of the structure of rearranged RTP packets added with error correction parity data;

FIG. 16 is a diagram illustrating an error correction process by the receiver unit of FIG. 12;

FIG. 17 is a flow chart illustrating a packet transmission process by the transmitter unit of FIG. 12;

FIG. 18 is a flow chart illustrating a packet reception process by the receiver unit of FIG. 12;

FIG. 19 is a block diagram showing another example of the structure of the transmitter unit of FIG. 12;

FIG. 20 is a flow chart illustrating another example of the packet transmission process by the transmitter unit of FIG. 12; and

FIG. 21 is a block diagram showing an example of the structure of an information processing apparatus according to an embodiment of the present invention.

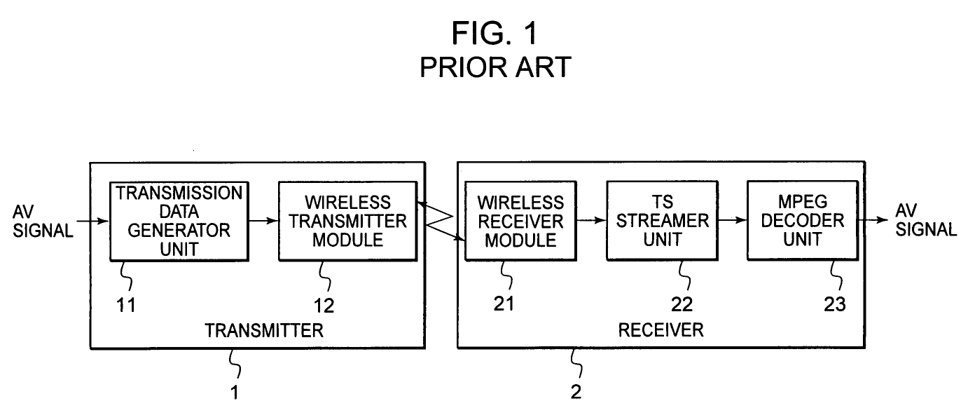

### DETAILED DESCRIPTION OF THE EMBODIMENTS

In the following description of embodiments of the present invention, the correspondence between the disclosed inventions and the embodiments is as follows. The description is used for confirming that the embodiments supporting the inventions described in this specification are described in the specification. Therefore, the embodiment described in this specification as not corresponding to some invention is not intended to mean that the embodiment does not correspond to the invention. Conversely, the embodiment described in this specification as corresponding to some invention is not intended to mean that the embodiment does not correspond to the invention other than some invention.

Further, the description is not intended to cover all the inventions described in the specification. In other words, it is not intended to deny the presence of the invention described in this specification but not claimed in this application, i.e., to deny the presence of the invention which may be divisionally submitted in the future and the invention emerging through corrections and additionally submitted in the future.

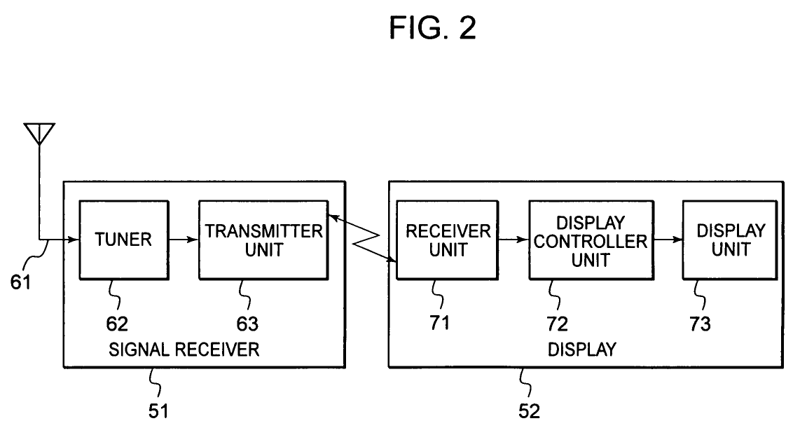

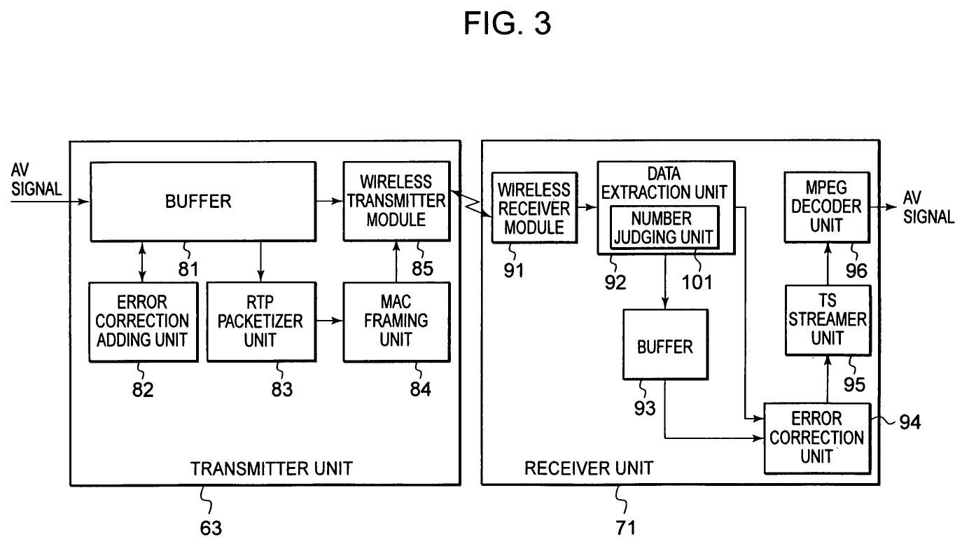

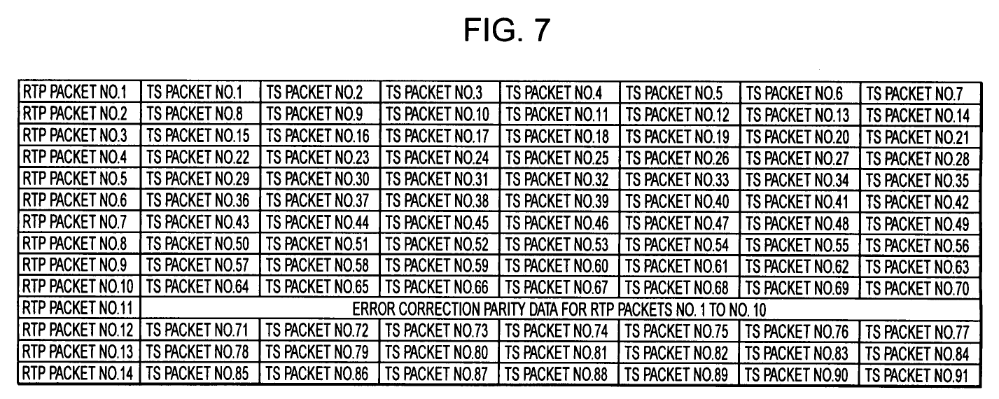

In a transmission/reception system according to an embodiment of the present invention, a transmitter (e.g., a signal receiver 51 of FIG. 2) includes error correction adding means (e.g., an error correction adding unit 82 of FIG. 3) for adding error correction data to each set of N (e.g., 70 in the case of FIG. 7) TS (Transport Stream) packets, RTP (Real-time Transport Protocol) packet generating means (e.g., an RTP packetizer 83 of FIG. 3) for generating an RTP packet by collecting M (e.g., 7 in the case of FIG. 7) (N>M) TS packets added with the error correction data by the error correction adding means and sequentially assigning a sequence number to each set of M TS packets, and transmitter means (e.g., a wireless transmitter module 85 of FIG. 3) for transmitting each RTP packet generated by the RTP packet by converting the RTP packets into data transmittable to a receiver, and that the receiver (e.g., a display 52 of FIG. 2) includes receiver means (e.g., a wireless receiver module 91 of FIG. 3) for receiving the data from the transmitter, packet acquiring means (e.g., a data extraction unit 92 of FIG. 3) for acquiring the RTP packet from the data received by the receiver means, packet judging means (e.g., a number judging unit 101 of FIG. 3) for judging, from the sequence number of the RTP packet acquired by the packet acquiring means, whether there is any dropped packet not received by the receiver means, and packet correcting means (e.g., an error correction unit 94 of FIG. 3) for correcting the dropped packet by using the RTP packets acquired by the packet acquiring means, if the packet judging means judges that there is a dropped packet not received.

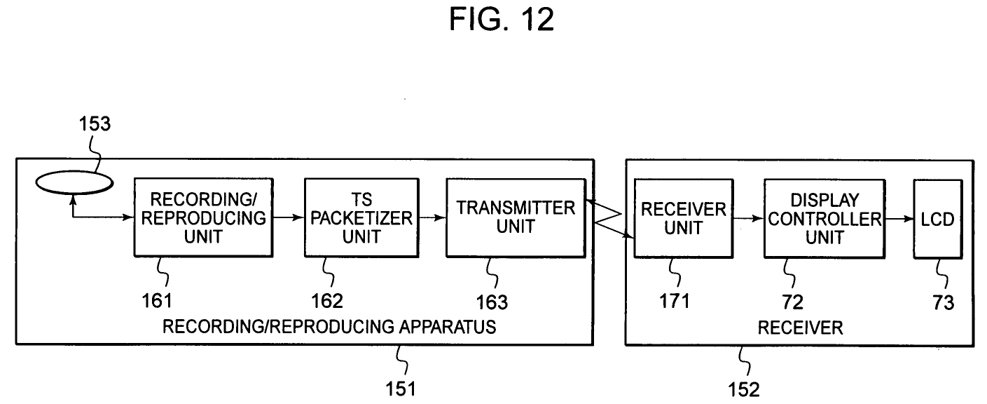

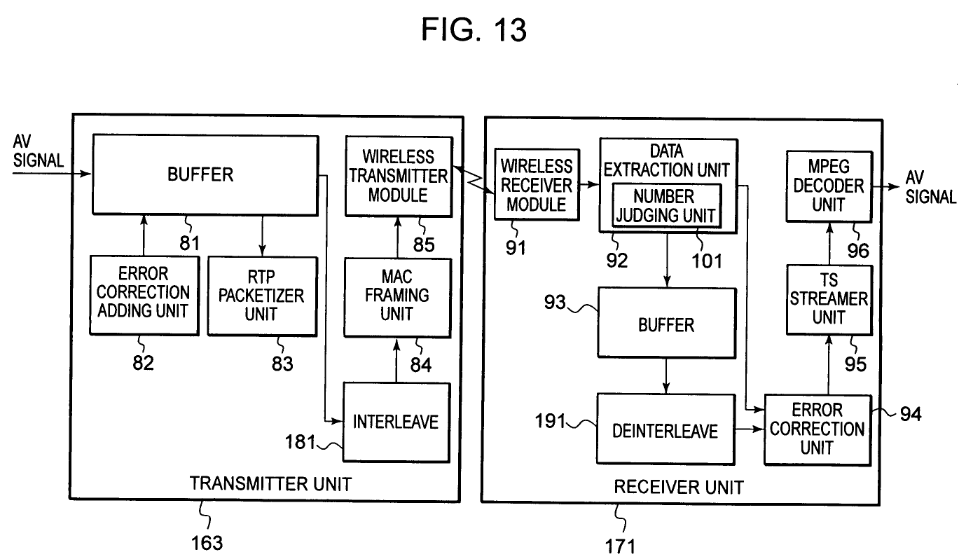

In a transmission/reception system according to another embodiment, the transmitter (e.g., a recording/reproducing apparatus 151 of FIG. 12) further includes interleaver means (e.g., an interleaver 181 of FIG. 13) for rearranging an order of the RTP packets generated by the RTP packet generating means to a predetermined order, before the RTP packets are transmitted by the transmitter means, and the receiver (e.g., a display 152 of FIG. 12) further includes deinterleaver means (e.g., a deinterleaver 191 of FIG. 13) for rearranging the order of the RTP packets acquired by the packet acquiring means to an original order before being rearranged to the predetermined order by the interleaver means.

A transmitter according to another embodiment (e.g., the signal receiver 51 of FIG. 2) includes error correction adding means (e.g., the error correction adding unit 82 of FIG. 3) for adding error correction data to each set of N (e.g., 70 in the case of FIG. 7) TS (Transport Stream) packets, RTP (Real-time Transport Protocol) packet generating means (e.g., the RTP packetizer unit 83 of FIG. 3) for generating an RTP packet by collecting M (e.g., 7 in the case of FIG. 7) (N>M) TS packets added with the error correction data by the error correction adding means and sequentially assigning a sequence number to each set of M TS packets, and transmitter means (e.g., the wireless transmitter module 85 of FIG. 3) for transmitting each RTP packet generated by the RTP packet generating means by converting the RTP packets into data transmittable to a receiver.

A transmitter according to another embodiment (e.g., the recording/reproducing apparatus 151 of FIG. 12) further includes interleaver means (e.g., the interleaver 181 of FIG. 13) for rearranging an order of the RTP packets generated by the RTP packet generating means to a predetermined order, before the RTP packets are transmitted by the transmitter means.

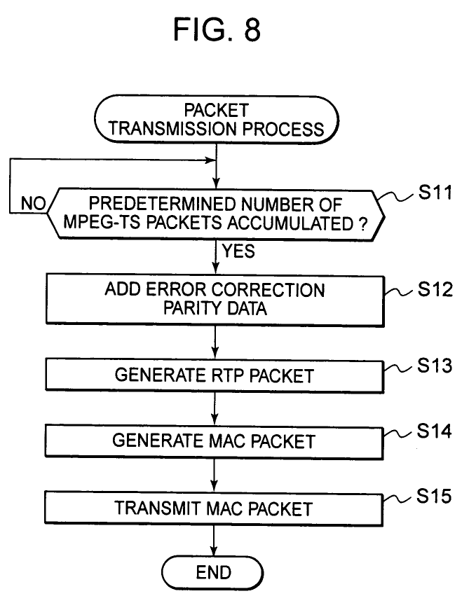

A transmitting method according to another embodiment includes an error correction adding step (e.g., Step S12 of FIG. 8) of adding error correction data to each set of N (e.g., 70 in the case of FIG. 7) TS (Transport Stream) packets, an RTP (Real-time Transport Protocol) packet generating step (e.g., Step S13 of FIG. 8) of generating an RTP packet by collecting M (e.g., 7 in the case of FIG. 7) (N>M) TS packets added with the error correction data by the error correction adding step and sequentially assigning a sequence number to each set of M TS packets, and a transmitting step (e.g., Step S14 of FIG. 8) of transmitting each RTP packet generated by the RTP packet generating step by converting the RTP packets into data transmittable to a receiver.

A recording medium according to another embodiment and a program according to still another embodiment provide basically similar processes to the transmitting method described above so that the description thereof is omitted because of duplication.

A receiver (e.g., the display 52 of FIG. 2) according to another embodiment includes receiver means (e.g., the wireless receiver module 91 of FIG. 3) for receiving data from a transmitter, the data including an RTP (Real-time Transport Protocol) packet generated by collecting M (e.g., 7 in the case of FIG. 7) TS packets added with the error correction data for N (e.g., 70 in the case of FIG. 7) (N>M) TS (Transport Stream) packets and sequentially assigning a sequence number to each set of M TS packets, packet acquiring means (e.g., the data extraction unit 92 of FIG. 3) for acquiring the RTP packet from the data received by the receiver means, packet judging means (e.g., the number judging unit 101 of FIG. 3) for judging, from the sequence number of the RTP packet acquired by the packet acquiring means, whether there is any dropped packet not received by the receiver means, and packet correcting means (e.g., the error correction unit 94 of FIG. 3) for correcting the dropped packet by using the RTP packets acquired by the packet acquiring means, if the packet judging means judges that there is a dropped packet not received.

A receiver (e.g., the display 152 of FIG. 12) according to another embodiment further includes deinterleaver means (e.g. the deinterleaver 191 of FIG. 13) wherein the RTP packets in the data received by the receiver means were rearranged to a predetermined order by the transmitter, the deinterleaver means rearranges the order of the RTP packets acquired by the packet acquiring means to an original order before being rearranged to the predetermined order by the transmitter.

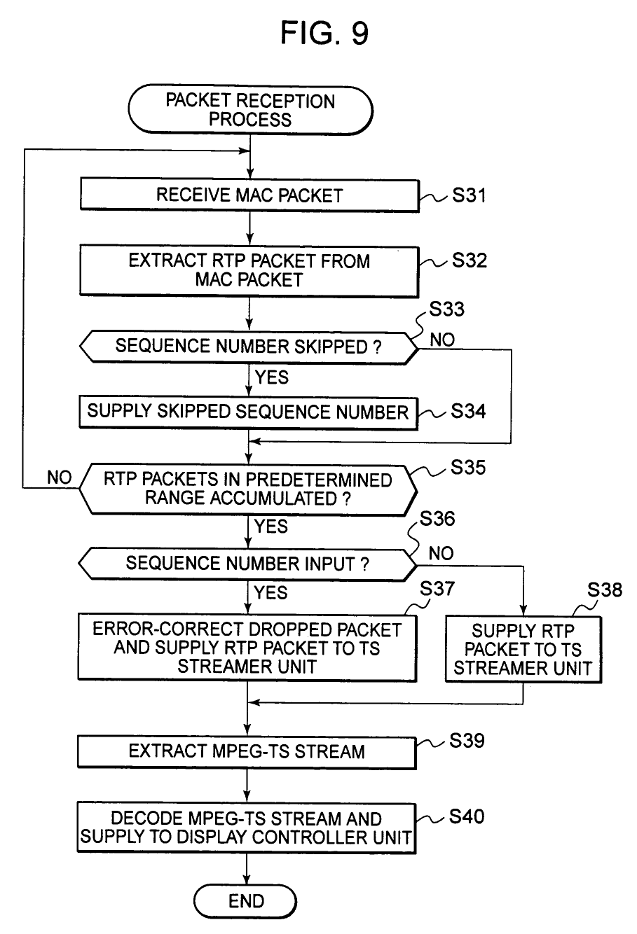

A receiving method according to another embodiment includes a receiving step (e.g., Step S31 of FIG. 9) of receiving data from a transmitter, the data including an RTP (Real-time Transport Protocol) packet generated by collecting M (e.g., 7 in the case of FIG. 7) TS packets added with the error correction data for N (e.g., 70 in the case of FIG. 7) (N>M) TS (Transport Stream) packets and sequentially assigning a sequence number to each set of M TS packets, a packet acquiring step (e.g., Step S32 of FIG. 9) of acquiring the RTP packet from the data received by the receiving step, a packet judging step (e.g., Step S33 of FIG. 9) of judging, from the sequence number of the RTP packet acquired by the packet acquiring step, whether there is any dropped packet not received by the receiver step, and a packet correcting step (e.g., Step S37 of FIG. 9) of correcting the dropped packet by using the RTP packets acquired by the packet acquiring step, if the packet judging step judges that there is a dropped packet not received.

A recording medium according to another embodiment and a program according to still another embodiment provide basically similar processes to the receiving method described above so that the description thereof is omitted to avoid duplication.

In the following, with reference to the accompanying drawings, embodiments of the present invention will be described.

FIG. 2 shows an example of the configuration of a transmission/reception system according to an embodiment of the present invention. In the example shown in FIG. 2, the transmission/reception system includes a signal receiver 51 and a display 52 for transmitting/receiving AV (Audio Video) data in real time.

The signal receiver 51 includes an antenna 61, a tuner 62 and a transmitter unit 63. The antenna 61 receives data of television broadcasting. The tuner 62 selects (detects and demodulates) an AV signal of a channel desired by a user, from data of the television broadcasting received at the antenna 61, and supplies the transmitter unit 63 with an AV signal of an MPEG-TS (Motion Picture Experts Group-Transport Stream) stream. The transmission unit 63 adds error correction parity data to the AV signal supplied from the tuner 62, converts it into transmittable data, and transmits it to a receiver unit 71 of the display 52.

The display 52 includes the receiver unit 71, a display controller unit 72 and a display unit 73. The receiver unit 71 receives data from the signal receiver 51 and executes error correction. The receiver unit 71 decodes the error-corrected data to generate an analog AV signal and output it to the display controller unit 72. The display controller unit 72 controls to display the AV signal from the receiver unit 71 on the display unit 73. The display unit 73 includes a CRT (Cathode Ray Tube), an LCD (Liquid Crystal Display) or the like, and displays an image based on the AV signal. Sounds of the AV signal are output from an speaker (not shown in the figure).

The signal receiver 51 and display 52 transfer data via wireless communications. Wireless communications are performed, for example, by the method based on IEEE802.11 standard. Since the signal receiver 51 and display 52 transfer data via wireless communications, for example, a user can view television broadcasting at a desired position where the display 52 is set, by fixedly installing the signal receiver 51 at a predetermined position in the house.

In the transmission/reception system constructed as above, an AV signal of television broadcasting received at the antenna 61 of the signal receiver 51 is supplied to the transmitter unit 63 via the tuner 62, and the transmitter unit 63 adds error correction parity data to the AV signal, converts it into transmittable data and transmits it through wireless communications in conformity with IEEE802.11 standard.

The receiver unit 71 of the display 52 receives data transmitted from the transmitter unit 63, executes error correction and decodes the data to obtain an AV signal. The receiver unit 71 supplies the decoded AV signal to the display controller unit 72 to display it on the display unit 73.

In the description of the example shown in FIG. 2, a digital signal of television broadcasting such as BS (Broadcasting Satellite) broadcasting, CS (Communications Satellite) broadcasting, and ground wave digital broadcasting is received by the signal receiver 51, and the data of the digital signal is transmitted to the display 52. Alternatively, the present invention may also be applicable to an analog signal of television broadcasting.

For example, a VTR (Video Tape Recorder), a DVD (Digital Versatile Disc) player or the like may be connected to the signal receiver 51 to transmit/receive data to and from these apparatuses. A recording/reproducing apparatus such as VTR may be connected to the display 52 to transmit/receive data to and from the apparatus. The signal receiver may be connected to a network such as the Internet to transmit/receive information from the network in accordance with the standard of IEEE802.3.

FIG. 3 shows an example of the structures of the transmitter unit 63 of the signal receiver 51 and the receiver unit 71 of the display 52 shown in FIG. 2.

The transmitter unit 63 includes a buffer 81, an error correction adding unit 82, an RTP (Real-time Transport Protocol) packetizer unit 83, a MAC (Media Access Control) framing unit 84 and a wireless transmitter module 85. The tuner 62 inputs an AV signal of the MPEG-TS stream to the buffer 81. The error correction adding unit 82 stands by, until a predetermined number of MPEG-TS packets (hereinafter simply called TS packet where appropriate) are stored in the buffer 81, and if it is judged that the predetermined number of TS packets are stored in the buffer 81, adds error correction parity data to the predetermined number of TS packets stored in the buffer 81. In the transmission/reception system, it is preset that the error correction parity data is added to how many TS packets (e.g., an error correction range), and the predetermined number of TS packets are obtained from this setting.

The RTP packetizer unit 83 collects a predetermined number of TS packets, e.g., seven TS packets, from the TS packets added with the error correction parity data and stored in the buffer 81, adds an RTP header to each group of the collected TA packets to generate an RTP packet and supply it to the MAC framing unit 84. In this case, the RTP packetizer unit 83 sequentially assigns a sequence number of the RTP header by incrementing by 1 at a time.

The MAC framing unit 84 adds a UDP (User Datagram Protocol) header to the RTP packet supplied from the RTP packet unit 83 to generate a UDP packet, adds an IP (Internet Protocol) header to the generated UDP packet to generate an IP packet, and adds a MAC (Media Access Control) header in conformity with IEEE802.11 to the generated IP packet to generate a MAC-framed packet (hereinafter called a MAC packet where appropriate) and supply it to the wireless transmitter module 85.

The wireless transmitter module 85 transmits the MAC packet supplied from the MAC framing unit 84 to the display 52 via wireless communications of IEEE802.11 standard.

The receiver unit 71 includes a wireless receiver module 91, a data extraction unit 92, a buffer 93, an error correction unit 94, a TS streaming unit 95, and an MPEG decoder unit 96. The wireless receiver module 91 receives a MAC packet transmitted from the signal receiver 51 via wireless communications of IEEE802.11 standard, and supplies the received MAC packet to the data extraction unit 92.

The data extraction unit 92 extracts the RTP packet from the MAC packet supplied from the wireless receiver module 91, and supplies the extracted RTP packet to the buffer 93. The data extraction unit 92 has a number judging unit 101. The number judging unit 101 judges whether the sequence number of the RTP header of the RTP packet extracted by the data extraction unit 92 increases by 1 at a time (i.e., whether the sequence number is skipped) . If it is judged that the sequence number of the RTP header of the extracted RTP packet is skipped, then it is judged that the RTP packet with the skipped sequence number was lost (packet dropped) from the communication line, and the number judging unit 94 supplies the skipped sequence number to the error correction unit 94.

The buffer 93 stores the RTP packets added with error correction parity data. The error correction unit 94 stands by, until the RTP packets in a predetermined range (i.e., with the sequence numbers in an error correction range) are stored in the buffer 93, and if it is judged that the RTP packets in the predetermined range are stored in the buffer 93, judges whether the sequence number was input from the number judging unit 101. If it is judged that the sequence number was input from the number judging unit 101, the error correction unit 94 executes error correction for the RTP packet with the sequence number supplied from the number judging unit 101, by using the predetermined number of RTP packets (including error correction parity data) stored in the buffer 93, and supplies the error-corrected RTP packets to the TS streaming unit 95. If it is judged that the number judging unit 101 did not input a sequence number, the error correction unit 94 supplies the RTP packets with the sequence numbers in the predetermined range stored in the buffer 93 directly to the TS streaming unit 95.

The TS streaming unit 95 extracts the MPEG-TS stream from the RTP packet supplied from the error correction unit 94 and stores it in an buffer (not shown in the figure). The MPEG decoder unit 96 decodes the MPEG-TS stream stored in the buffer of the TS streaming unit 95, and supplies the decoded AV signal to the display controller unit 72.

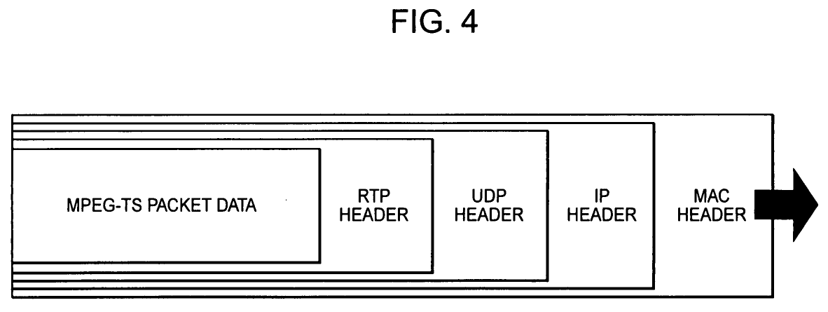

FIG. 4 shows an example of the structure of a MAC packet to be transmitted from the transmitter unit 63 to the receiver unit 71.

The transmitter unit 63 capusulizes a TS packet into, for example, a MAC layer, an IP layer, a UDP layer and an RTP layer.

Specifically, the RTP packetizer unit 83 of the transmitter 63 collects the proper number of TS packets to generate an RTP packet. A payload (data portion) of the RTP packet is MPEG-TS packet data. A header portion of the RTP packet is an RTP header. Although the proper number of TS packets (188 Byte per one packet) are inserted into the payload of the RTP packet, the proper number is generally set to seven. This is because a general transmission/reception system cannot be limited to 1:1 transmission/reception of only wireless communications, but often uses wired transmission/reception. Namely, since the payload of an RTP packet is made of 2312 Byte at the maximum in wireless communications of IEEE802.11 standard, TS packets more than seven can be inserted. However, according to the standard of IEEE802.3 for Ethernet®, data of only 1500 Byte (i.e., only up to seven TS packets) can be inserted into the payload of an RTP packet.

The MAC framing unit 84 of the transmitter unit 63 adds a UDP header to the RTP packet to generate a UDP packet for real time transmission. The MAC framing unit 84 further adds an IP header to the UDP packet, the IP header including a transmission source IP address, a transmission destination IP address and the like, to generate an IP packet, and adds a MAC header in conformity with IEEE802.11 to the IP packet to generate a MAC frame (MAC packet).

In the description of FIG. 3, although the UDP header is added to the RTP packet to generate the UDP packet for real time transmission, not only the UDP header but also a TCP (Transmission Control Protocol) header may be added to generate a TCP packet.

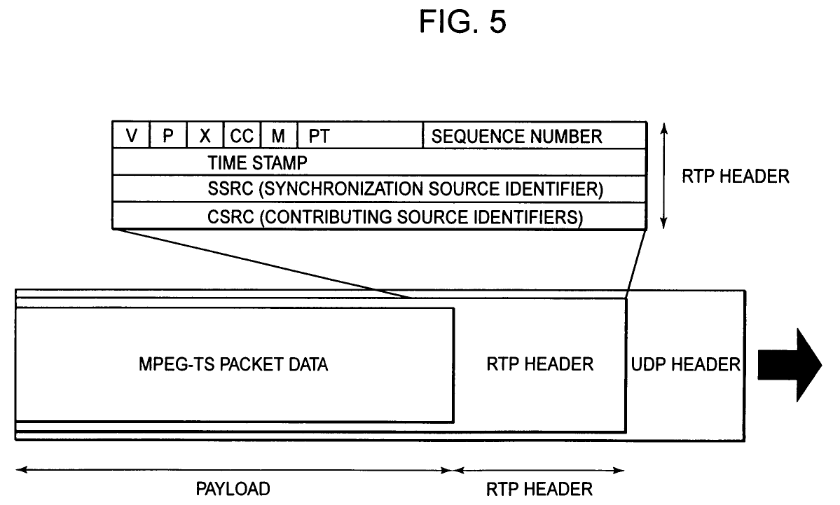

FIG. 5 is a diagram showing the data structure of an RTP header in the RTP layer. “V” in the RTP header represents Version Bit and provides information of the version number representative of a version of the format of the RTP header. “P” represents Padding Bit and is a bit for adjusting the size of the packet. “X” represents Extension Bit and is an extension bit designated if a function is extended.

“CC” represents CSRC (Contributing Source) Count and provides information of a counter indicating the number of sources to be mixed if the transmission source for real time transfer is a mixer. “M” represents Marker Bit and is a marker bit indicating a frame boundary of one packet. “PT” represents Payload Type and provides information representative of the type of payload coding. “Sequence Number” represents information representative of a sequence number indicating the order of the RTP packet. This sequence number can be expressed by a numerical value of two-byte length.

“TIME STAMP” provides information of a time stamp indicating the time when the RTP header is formed. “SSRC” represents Synchronization Source Identifier and provides information of a synchronization source identifier for identifying a first transmission source of a message. “CSRC” represents Contributing Source Identifiers and provides information of contribution source identifiers for identifying sources if a synchronization source is a mixer.

The payload corresponding to the RTP header containing the above-described information starts from the header of an MPEG-TS packet. Data of MPEG-TS packets, e.g., seven packets, is inserted into the payload.

The MPEG-TS packet data itself can be transmitted as a UDP packet without capsulizing it into the RTP layer. In this case, however, information of the time stamp cannot be obtained. Therefore, the transmitter unit 63 and receiver unit 71 packetize the MPEG-TS packet into an RTP packet and obtains the information of the time stamp from the RTP header constructed as described above. Namely, the transmitter unit 63 and receiver unit 71 packetize the MPEG-TS packet into the RTP packet and transmit it. Therefore, even if there is a packet drop from a communication line, mutual time synchronization can be performed correctly by using the time stamp of the RTP header.

A number representative of a packet order, such as a sequence number, is not defined for the MPEG-TS packet so that it is not possible to judge only from the MPEG-TS packet whether there is any packet drop from the communication line. To avoid this, the transmitter unit 63 and receiver unit 71 execute error correction by using the sequence number of the RTP header. Namely, the transmitter unit 63 sequentially assigns the RTP packet with a sequence number incremented by 1 at a time. The receiver unit 71 monitors this sequence number, and if a case occurs such that the sequence number is not increased by 1 at a time, but skips, stores this skipped sequence number. By referring to the skipped sequence number, the receiver unit 71 can execute error correction of the skipped (i.e., dropped from the communication line) RTP packet.

The sequence number to be assigned is not limited to the sequence number incremented by 1 at a time, but it may be incremented by 2 at a time. Namely, the numerical value to be incremented may be any number, if it is preset between the transmitter unit 63 and receiver unit 71 and the order of the sequence number can be confirmed.

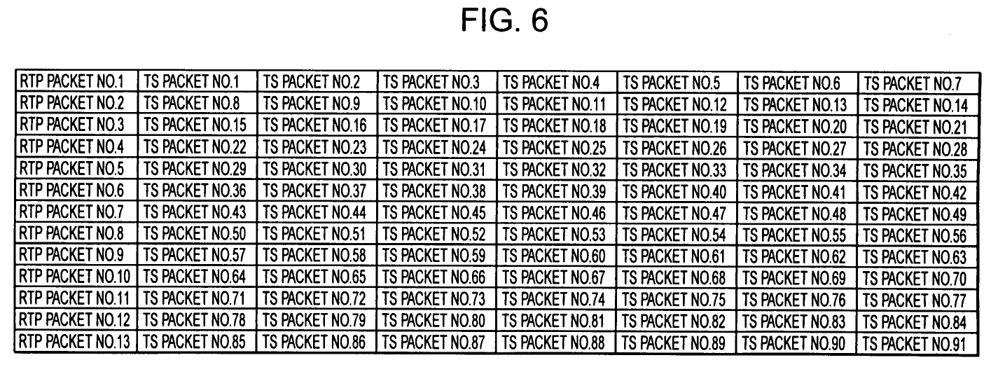

Next, with reference to FIGS. 6 and 7, description will be made on an example of error correction parity data to be added to the RTP packet. For the purposes of description convenience, in FIGS. 6 and 7, although a serial number is assigned to the TS packet, the sequence number representative of the order of a packet does not exist in the TS packet in an actual case as described earlier.

FIG. 6 shows an example of the structure of general RTP packets. In the example shown in FIG. 6, the RTP packet (RTP Packet) with the number 1 (No. 1) includes seven TS packets (TS Packet) with the number 1 (No. 1) to the number 7 (No. 7). Similarly, the RTP packet with the number 2 includes TS packets with the number 8 to the number 14, the RTP packet with the number 3 includes TS packets with the number 15 to the number 21, the RTP packet with the number 4 includes TS packets with the number 22 to the number 28, the RTP packet with the number 5 includes TS packets with the number 29 to the number 35, the RTP packet with the number 6 includes TS packets with the number 36 to the number 42, and the RTP packet with the number 7 includes TS packets with the number 43 to the number 49.

The RTP packet with the number 8 includes TS packets with the number 50 to the number 56, the RTP packet with the number 9 includes TS packets with the number 57 to the number 63, the RTP packet with the number 10 includes TS packets with the number 64 to the number 70, the RTP packet with the number 11 includes TS packets with the number 71 to the number 77, the RTP packet with the number 12 includes TS packets with the number 78 to the number 84, and the RTP packet with the number 13 includes TS packets with the number 85 to the number 91.

In the example shown in FIG. 6, since the RTP packets from the fourteenth RTP packet and succeeding packets have similar fundamental structures, they are omitted in FIG. 6.

FIG. 7 shows an example of the structure of RTP packets added with error correction parity data. In the example of FIG. 7, one set of error correction parity data using, for example, the Reed-Solomon code, is added to ten RTP packets constituted as shown in FIG. 6. In this case, since one error correction parity RTP packet is added to ten RTP packets, if a data rate of the general RTP packet (not added with error correction parity data) of FIG. 6 is 20 Mbps, then the data rate of the RTP packet after the error correction parity data is added as shown in FIG. 7 is 22 Mbps.

Therefore, in the example of FIG. 7, the structure up to the RTP packet with the number 10 is the same as that shown in FIG. 6, and the RTP packet with the number 11 includes error correction parity data for the RTP packets with the number 1 to the number 10. Namely, the RTP packet with the number 11 is an error correction parity RTP packet for the number 1 to the number 10.

This addition of the error correction parity data changes the structure of the succeeding RTP packets. Namely, the RTP packet with the number 12 includes the TS packets with the number 71 to the number 77, the RTP packet with the number 13 includes the TS packets with the number 78 to the number 84, and the RTP packet with the number 14 includes the TS packets with the number 85 to the number 91.

Also in the example of FIG. 7, since the RTP packets from the fourteenth RTP packet and succeeding packets have similar fundamental structures, they are omitted in FIG. 7. However, for example, the RTP packet with the number 22 includes error correction parity data for the RTP packets with the number 12 to the number 21, and the RTP packet with the number 33 includes error correction parity data for the RTP packets with the number 23 to the number 32.

With the error correction parity data added in the manner described above, error correction is possible even if one RTP packet is dropped among the RTP packets with the number 1 to the number 11 containing the error correction parity RTP packet (RTP packet with the number 11). The transmitter unit 63 and receiver unit 71 preset an error correction parity data addition method as to how many error correction parity RTP packets are added to how many RTP packets. Therefore, the receiver unit 71 can execute error correction and recover the dropped RTP packet, in accordance with the RTP packets correctly arrived at the error correction unit 94 and the sequence number of the dropped RTP packet.

In the description of the example of FIG. 7, although the error correction parity is added only along one direction by using the Reed-Solomon code, the error correction parity data may be added along two directions, vertical and horizontal directions, or another type of error correction parity data may also be used.

Next, with reference to the flow chart of FIG. 8, description will be made on a transmission process by the transmitter unit 63 of the signal receiver 51.

The tuner 62 selects (detects and demodulates) an AV signal of a channel desired by a user, from data of television broadcasting received at the antenna 61, and supplies the AV signal of the MPEG-TS stream to the buffer 81.

At Step S11 the error correction adding unit 82 stands by, until the predetermined number of MPEG-TS packets are stored in the buffer 81, and if it is judged that the predetermined number of TS packets are stored in the buffer 81, the flow proceeds to Step S12 whereat error correction parity data is added to the predetermined number of TS packets stored in the buffer 81 to thereafter proceed to Step S13. For example, in the example of FIG. 7, in order to add the error correction parity data to ten RTP packets, the error correction adding unit 82 stands by until seventy TS packets (corresponding to ten RTP packets) are stored, and then adds the error correction parity data to the seventy TS packets.

At Step S13 the RTP packetizer unit 83 collects the predetermined number (in the example of FIG. 7, seven) of TS packets among the TS packets added with the error correction parity data stored in the buffer 81, and adds the RTP header to the collected TS packets to generate an RTP packet and supply it to the MAC framing unit 84 to thereafter proceed to Step S14. In this case, the RTP packetizer unit 83 sequentially assigns the sequence number of the RTP header by incrementing by 1 at a time.

At Step S14 the MAC framing unit 84 adds a UDP header to the RTP packet supplied from the RTP packetizer unit 83 to generate a UDP packet, adds an IP header to the generated UDP packet to generate an IP packet, adds a MAC header to the generated IP packet to generate a MAC packet structured as described earlier with FIG. 4, and supplies it to the wireless transmitter module 85 to thereafter proceed to Step S15.

At Step S15 the wireless transmitter module 85 transmits the MAC packet supplied from the MAC framing unit 84 to the display 52 via wireless communications of IEEE802.11 standard to thereafter terminate the packet transmission process.

With reference to the flow chart of FIG. 9, description will be made on a packet reception process by the receiver unit 71 of the display 52 to be executed in response to the packet transmission process by the transmitter unit 63 described above.

A MAC packet is transmitted from the transmitter unit 51 of the signal receiver 63 via wireless communications of IEEE802.11 standard. At Step S31 the wireless receiver module 91 receives the MAC packet transmitted from the signal receiver 51, and supplies the received MAC packet to the data extraction unit 92 to thereafter proceed to Step S32.

At Step S32 the data extraction unit 92 extracts an RTP packet from the MAC packet supplied from the wireless receiver module 91, and supplies the extracted RTP packet to the error correction unit 94 to thereafter proceed to Step S33. At Step S33 the number judging unit 101 judges whether the sequence number of the RTP header of the RTP packet extracted by the data extraction unit 92 increases by 1 at a time, and if it is judged that the sequence number of the RTP header of the extracted RTP packet does not increase by 1 at a time (i.e., skips), judges that the RTP packet with the skipped sequence number was dropped from the communication line to thereafter proceed to Step S34 whereat the skipped sequence number is supplied to the error correction unit 94 to thereafter proceed to Step S35.

If it is judged at Step S33 that the sequence number of the RTP header of the extracted RTP packet increases by 1 at a time (i.e., does not skip), the number judging unit 101 skips the process at Step S34 to proceed to Step S35.

The RTP packets added with error correction parity data are being stored in the buffer 93. At Step S35 the error correction unit 94 judges whether the RTP packets (RTP packets with the number 1 to the number 11, in the example of FIG. 7) in the predetermined range (i.e., with the sequence numbers in the error correction range) are stored in the buffer 93. If it is judged that the RTP packets in the predetermined range are not stored, the flow returns to Step S31 to repeat the succeeding processes.

If it is judged at Step S35 that the RTP packets in the predetermined range are stored, the flow proceeds to Step S36 whereat the error correction unit 94 judges whether a sequence number was input by the number judging unit 101. If it is judged at Step S36 that a sequence number was input by the number judging unit 101, the flow proceeds to Step S37 whereat the error correction unit 94 executes error correction for the RTP packet with the sequence number supplied from the number judging unit 101, by using the predetermined number of RTP packets stored in the buffer 93 including the error correction parity data (in the example of FIG. 7, the RTP packet with the number 11). Namely, executing the error correction recovers the RTP packet with the sequence number supplied from the number judging unit 101. The error correction unit 94 supplies the RTP packets subjected to the error correction to the TS streaming unit 95 to thereafter proceed to Step S39.

If it is judged at Step S36 that a sequence number was not input by the number judging unit 101, the flow proceeds to Step S38 whereat the error correction unit 94 supplies the RTP packets in the predetermined range stored in the buffer 93, directly to the TS streaming unit 95 to thereafter proceed to Step S39.

At Step S39 the TS streaming unit 95 obtains MPEG-TS streams excluding the error correction parity from the RTP packets supplied from the error correction unit 94, and stores the streams in an buffer (not shown in the figure) to thereafter proceed to Step S40. At Step S40 the MPEG decoder unit 96 decodes the MPEG-TS streams stored in the buffer of the TS streaming unit 95, and supplies the decoded AV signal to the display controller unit 72 to thereafter terminate the packet reception process. The display controller unit controls to display the AV signal from the MPEG decoder unit 96 on the display unit 73 so that an image based on the AV signal is displayed on the display unit 73.

As described above, the transmitter unit 63 adds error correction parity data to the TS packets to generate RTP packets and sequentially assigns the sequence number incremented by 1 at a time to each of the RTP packets added with the error correction parity data. Accordingly, the receiver unit 71 can execute error correction with ease only by confirming the sequence number. Namely, only by presetting the range of RTP packets to be subjected to error correction and the like between the transmitter unit 63 and receiver unit 71, a transmission/reception system can be configured easily because it is unnecessary to newly define an error correction mechanism for the transmitter unit 63 and receiver unit 71 and to prepare special functions for the mechanism.

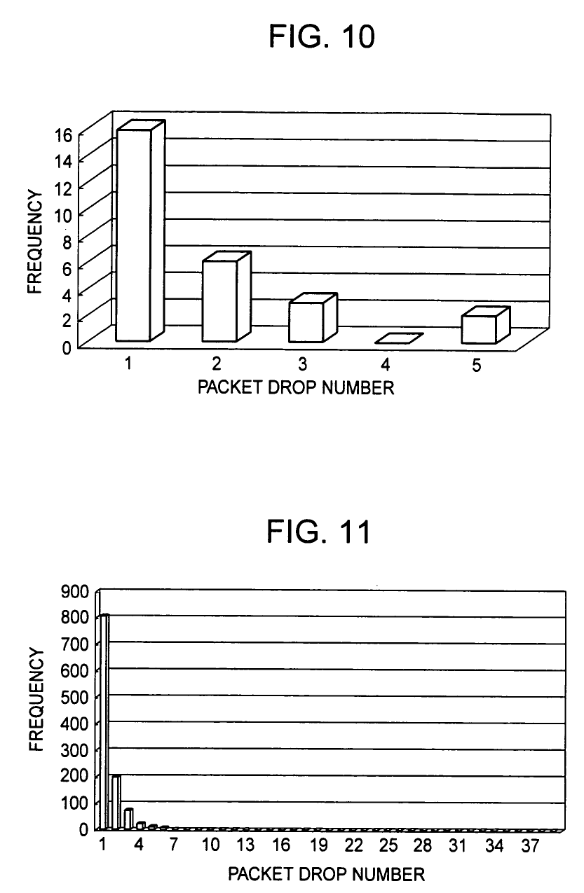

FIG. 10 is a graph showing a packet drop state if communication conditions are good. In the example of FIG. 10, the abscissa represents the number of packet drops among total 503,633 packets in communications and the ordinate represents a frequency.

The example of FIG. 10 indicates that the frequency that one packet drop occurs in the total 503,633 packets is 16 times, the frequency of occurrence of two packet drops is 6 times, and the frequency of occurrence of three packet drops is 3 times. It also indicates that the frequency that four packet drops occur in the total 503,633 packets is 0 time, and the frequency of occurrence of five packet drops is twice.

FIG. 11 is a graph showing a packet drop state if wireless communication conditions are bad such as over-the-wall communications. In the example of FIG. 11, the abscissa represents the number of packet drops among total 147,988 packets in communications and the ordinate represents a frequency.

The example of FIG. 11 indicates that the frequency that one packet drop occurs in the total 147,988 packets is 812 times, the frequency of occurrence of two packet drops is 202 times, the frequency of occurrence of three packet drops is 74 times, and the frequency of occurrence of four packet drops is 25 times. It also indicates that the frequency that five packet drops occur in the total 147,988 packets is 13 times, and the frequency of occurrence of six packet drops is 4 times.

It also indicates that the frequencies that 7, 14, and 16 packet drops occur in the total 147,988 packets are all twice, and the frequencies of occurrence of 8 to 10, 12, 15, 20 to 22, 29, 30, 35, 38 and 39 are all once, and the frequencies of occurrence of 11, 13, 17 to 19, 23 to 28, 31 to 34, 36 and 37 packet drops are all 0 time.

In the error correction of the transmission/reception system described above with FIG. 2, for example one error correction RTP packet is added to ten RTP packets so that only one RTP packet per eleven RTP packets can be subjected to error correction. Namely, under the good communication conditions in the example of FIG. 10, the frequency of the number (packet drop number larger than once) which the error correction by the transmission/reception system of FIG. 2 cannot deal with is 11 times. However, since these packet drops may not occur in succession in some cases, there are many cases which the error correction by the transmission/reception system of FIG. 2 can be executed. It can therefore be said that the error correction by the transmission/reception system of FIG. 2 is effective for packet drops under the good communication conditions.

However, as shown in FIG. 11, under the bad wireless communication conditions due to over-the-wall or the like, the frequency of the number (packet drop number larger than once) which the error correction by the transmission/reception system of FIG. 2 cannot be made is 337 times. Further, under the bad wireless communication conditions, packet drops may occur often in succession in a burst manner. It can therefore be said that the error correction by the transmission/reception system of FIG. 2 is not effective for packet drops under the bad wireless communication conditions. Under the bad wireless communication conditions, it is considered that a transmission/reception system is effective which interleaves (rearranges) RTP packets added with error correction parity data before transmission, in the manner such as shown in FIG. 12.

FIG. 12 shows another example of the transmission/reception system according to another embodiment of the present invention. In FIG. 12, units corresponding to those shown in FIG. 2 are represented using corresponding symbols, and the description thereof is omitted because of duplication. In the example shown in FIG. 12, the transmission/reception system includes a recording/reproducing apparatus 151 and a display 152.

An optical disk 153 can be removably loaded in the recording/reproducing apparatus 151. For example, the optical disk 153 is a DVD (Digital Versatile Disk) or the like. The recording/reproducing apparatus 151 records data in the optical disk, and reads and reproduces data recorded in the optical disk 153.

The recording/reproducing apparatus 151 includes a recording/reproducing unit 161, a TS packetizer unit 162 and a transmitter unit 163. The recording/reproducing unit 161 reads data recorded in the optical disk 153 loaded in the recording/reproducing apparatus 151, and records data received at an antenna (not shown in the figure) or data acquired from an network (not shown in the figure) or the like, in the optical disk 153. The recording/reproducing unit 161 supplies data read from the optical disk 153 to the TS packetizer unit 162. The TS packetizer unit 162 converts the data supplied from the recording/reproducing unit 161 into an AV signal of the MPEG-TS stream, and supplies the converted AV signal to the transmitter unit 163. The transmitter unit 163 adds error correction parity data to the AV signal supplied from the TS packetizer unit 162, rearranges the order of data added with the error parity and converts the data into transmittable data to transmit it to a receiver unit 171 of the display 152.

The display 152 includes the receiver unit 171, a display controller unit 72 and a display unit 73. The receiver unit 171 receives data from the recording/reproducing apparatus 151, rearranges the order of the received data to the original order and executes error correction. The receiver unit 171 decodes the data subjected to the error correction to obtain an AV signal which is output to the display controller unit 72. The display controller unit 72 controls to display the AV signal from the receiver unit 171 on the display unit 73. The display unit 73 displays an image based on the AV signal.

Since the recording/reproducing apparatus 151 and display 152 transfer data via wireless communications, for example, a user can view AV data read from the optical disk 153 at a desired position where the display 152 is set, by fixedly installing the recording/reproducing apparatus 151 at a predetermined position in the house.

In the transmission/reception system constructed as above, an AV signal of the optical disk 153 read by the recording/reproducing unit 161 of the recording/reproducing apparatus 151 is supplied to the transmitter unit 163 via the TS packetizer unit 162, and the transmitter unit 163 adds error correction parity data to the AV signal, rearranges the order, converts the data into transmittable data and transmits it through wireless communications in conformity with the standards of IEEE802.11.

The receiver unit 171 of the display 152 receives data transmitted from the transmitter unit 163, rearranges the data to the original order, executes error correction and decodes the data to obtain an AV signal. The receiver unit 171 supplies the decoded AV signal to the display controller unit 72 to display it on the display unit 73.

FIG. 13 shows an example of the structures of the transmitter unit 163 of the recording/reproducing apparatus 151 and the receiver unit 171 of the display 152 shown in FIG. 12. The transmitter unit 163 shown in FIG. 13 has a similar structure to that of the transmitter unit 63 shown in FIG. 3, excepting that an interleaver 181 is added. The receiver unit 171 shown in FIG. 13 has a similar structure to that of the receiver unit 71 shown in FIG. 3, excepting that a deinterleaver 191 is added.

The transmitter unit 163 includes a buffer 81, an error correction adding unit 82, an RTP packetizer unit 83, the interleaver 181, a MAC framing unit 84 and a wireless transmitter module 85.

In the example of FIG. 13, the RTP packetizer unit 83 of the transmitter unit 163 collects a predetermined number of TS packets, e.g., seven TS packets, from the TS packets added with the error correction parity data and stored in the buffer 81, and adds an RTP header sequentially assigned the sequence number to each group of the collected TA packets to generate an RTP packet. The interleaver 181 rearranges the RTP packets generated by the RTP packetizer unit 83 and stored in the buffer 81 to have a predetermined order, and supplies the rearranged RTP packets to the MAC framing unit 84. The order rearranged by the interleaver 181 is preset between the transmitter unit 163 and receiver unit 171.

The MAC framing unit 84 adds a UDP header to the RTP packet rearranged by the interleaver 181 to generate a UDP packet, adds an IP header to the generated UDP packet to generate an IP packet, adds a MAC header to the generated IP packet to generate a MAC packet, and supplies it to the wireless transmitter module 85.

The receiver unit 171 includes a wireless receiver module 91, a data extraction unit 92, a buffer 93, a deinterleaver 191, an error correction unit 94, a TS streaming unit 95, and an MPEG decoder unit 96.

In the example of FIG. 13, the data extraction unit 92 extracts the RTP packet from the MAC packet supplied from the wireless receiver module 91, and supplies the extracted RTP packet to the buffer 93. The order of the RTP packets were rearranged by the interleaver 181. Therefore, the number judging unit 101 judges whether the sequence number of the RTP header is skipped, by judging whether the sequence numbers of the RTP headers of the RTP packets extracted by the data extraction unit 92 have the order rearranged by the interleaver 181. If it is judged that the sequence number of the RTP header of the extracted RTP packet is skipped, it is judged that the RTP packet with the skipped sequence number was lost (packet drop) from the communication line, and the skipped sequence number is supplied to the error correction unit 94.

The buffer 93 stores the RTP packets added with error correction parity data and having the order rearranged by the interleaver 181. The deinterleaver 191 stands by, until the RTP packets in a predetermined range (i.e., with the sequence numbers in an error correction range) are stored in the buffer 93, and if it is judged that the RTP packets in the predetermined range are stored in the buffer 93, rearranges the RTP packets rearranged by the interleaver 181 to have the original order, and supplies them to the error correction unit 94.

If the error correction unit 94 receives the RTP packets from the deinterleaver 181, it judges whether the sequence number was input from the number judging unit 101, and if it is judged that the sequence number was input, the error correction unit 94 executes error correction for the RTP packet having the sequence number input from the number judging unit 101, by using the predetermined number (i.e., in the error correction range) of RTP packets with the error correction parity data, and supplies error-corrected RTP packets to the TS streaming unit 95. If it is judged that the sequence number was not input from the number judging unit 101, the error correction unit 94 supplies the predetermined number of RTP packets supplied from the deinterleaver 191 directly to the TS streaming unit 95.

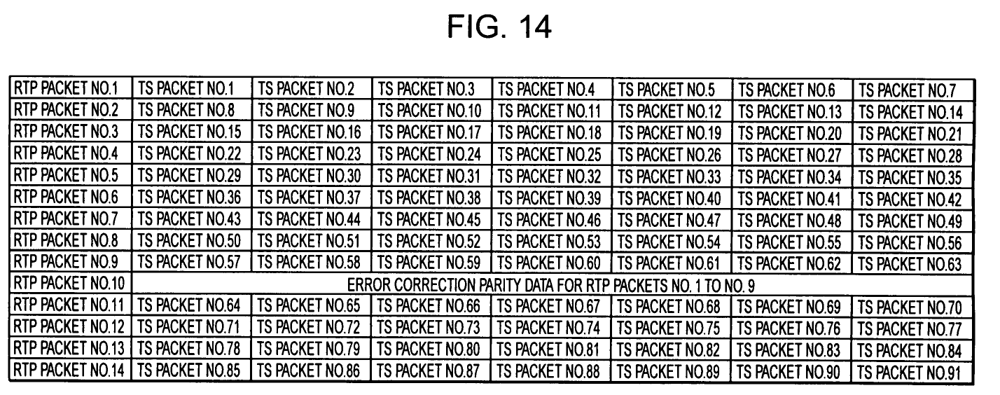

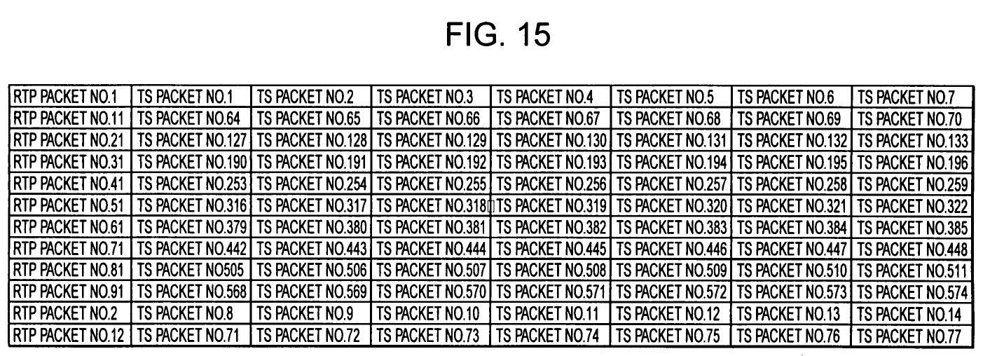

Next, with reference to FIGS. 14 and 15, description will be made on rearranging the order of RTP packets added with error parity data.

FIG. 14 shows an example of the structure of RTP packets with error correction parity data. In FIG. 14, one set of error correction parity data using, for example, the Reed-Solomon code, is added to nine RTP packets constituted as shown in FIG. 6. Therefore, in the example shown in FIG. 14, the RTP packets up to the RTP packet with the number 9 have the same structure as that shown in FIG. 6, and the RTP packet with the number 10 includes the error correction parity data for the RTP packets with the number 1 the number 9. Namely, the RTP packet with the number 10 is an error correction parity packet for the RTP packets with the number 1 to the number 9.

This addition of the error correction parity data changes the structure of the succeeding RTP packets. Therefore, the RTP packet with the number 11 includes the TS packets with the number 64 to the number 70, the RTP packet with the number 12 includes the TS packets with the number 71 to the number 77, the RTP packet with the number 13 includes the TS packets with the number 78 to the number 84, and the RTP packet with the number 14 includes the TS packets with the number 85 to the number 91.

Since the RTP packets from the fifteenth RTP packet and succeeding packets have similar fundamental structures, they are omitted in FIG. 14. However, for example, the RTP packet with the number 20 includes error correction parity data for the RTP packets with the number 11 to the number 19, and the RTP packet with the number 30 includes error correction parity data for the RTP packets with the number 21 to the number 29.

With the error correction parity data added in the manner described above, error correction is possible even if one RTP packet is dropped among the RTP packets with the number 1 to the number 10 containing the error correction parity RTP packet (RTP packet with the number 10).

FIG. 15 shows an example of the structure of rearranged RTP packets added with error correction parity data. In the example shown in FIG. 15, the RTP packets added with the error correction parity data shown in FIG. 14 are rearranged in the unit of ten packets.

Namely, after the RTP packet with the number 1 constituted of the TS packets with the number 1 to the number 7, the RTP packet with the number 11 constituted of the TS packets with the number 64 to the number 70 is disposed. After the RTP packet with the number 11, the RTP packet with the number 21 constituted of the TS packets with the number 127 to the number 133 is disposed. After the RTP packet with the number 21, the RTP packet with the number 31 constituted of the TS packets with the number 190 to the number 196 is disposed. After the RTP packet with the number 31, the RTP packet with the number 41 constituted of the TS packets with the number 253 to the number 259 is disposed.

After the RTP packet with the number 41, the RTP packet with the number 51 constituted of the TS packets with the number 316 to the number 322 is disposed. After the RTP packet with the number 51, the RTP packet with the number 61 constituted of the TS packets with the number 379 to the number 385 is disposed. After the RTP packet with the number 61, the RTP packet with the number 71 constituted of the TS packets with the number 442 to the number 448 is disposed.

After the RTP packet with the number 71, the RTP packet with the number 81 constituted of the TS packets with the number 505 to the number 511 is disposed. After the RTP packet with the number 81, the RTP packet with the number 91 constituted of the TS packets with the number 568 to the number 574 is disposed. After the RTP packet with the number 91, the RTP packet with the number 2 constituted of the TS packets with the number 8 to the number 14 is disposed. After the RTP packet with the number 2, the RTP packet with the number 12 constituted of the TS packets with the number 71 to the number 77 is disposed.

The interleaver 181 of the transmitter unit 163 rearranges the order of the RTP packets having the structure shown in FIG. 14 to the order of the RTP packets having the structure shown in FIG. 15. Therefore, the transmitter unit 163 transmits MAC packets having the RTP packets whose order was rearranged. The receiver unit 171 receives the MAC packets having the RTP packets whose order was rearranged. Therefore, the deinterleaver 191 rearranges the order of the rearranged RTP packets shown in FIG. 15 to the original order of the RTP packets shown in FIG. 14.

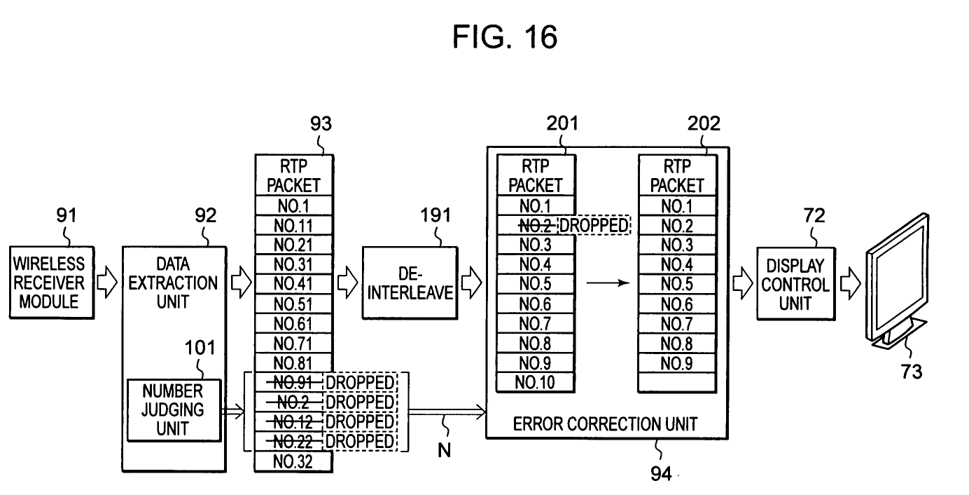

FIG. 16 is a diagram specifically illustrating the error correction process by the receiver unit 171 shown in FIG. 13. In the example shown in FIG. 16, description will be made on the error correction process using the error correction parity data and rearrangement described above with reference to FIGS. 14 and 15. In FIG. 16, the TS streaming unit 95 and MPEG decoder unit 96 of the receiver unit 171 are shown omitted.

In the example shown in FIG. 16, arrows indicate the data flow. The wireless receiver unit 91 receives the MAC packet transmitted from the recording/reproducing apparatus 151, and supplies the received MAC packet to the data extraction unit 92. The data extraction unit 92 extracts the RTP packet from the MAC packet supplied from the wireless receiver module 91, and supplies the extracted RTP packet to the buffer 93.

The buffer 93 stores the RTP packets rearranged in the manner described with reference to FIG. 15 and added with the error correction parity data by the recording/reproducing apparatus 151. Therefore, in the normal state without any packet drop from the communication line, the buffer 93 stores the RTP packets in the sequence number order of 1, 11, 21, 31, 41, 51, 61, 71, 81, 91, 2, 12, 22, and 32. However, in the example shown in FIG. 16, the RTP packets with the sequence numbers 91, 2, 12 and 22 were dropped from the communication line and are not stored in the buffer 93.

At the same time if the data extraction unit 92 extracts the RTP packet from the MAC packet supplied from the wireless receiver module 91, the number judging unit 101 judges whether the sequence numbers of the RTP headers of the RTP packets extracted by the data extraction unit 92 have the order rearranged by the interleaver 181 (i.e., whether the sequence number of the RTP header is not skipped), to thereby acquire the skipped sequence number, i.e., the sequence number of the RTP packet dropped from the communication line. The data extraction unit 92 supplies the error correction unit 94 with the sequence numbers N (sequence numbers 91, 2, 12 and 22) of the RTP packets not stored in the buffer 93.

The deinterleaver 191 rearranges the RTP packets stored in the buffer 93 to the original order before the interleaver 181 rearranges, and supplies the rearranged RTP packets 201 to the error correction unit 94. For example, the RTP packets are supplied in the sequence number order of 1, (2), 3, 4, 5, 6, 7, 8, 9 and 10. In this case, the RTP packet with the sequence number 2 was dropped so that it is not supplied.

The RTP packet with the sequence number 10 is the error correction parity RTP packet. The error correction unit 94 has already been supplied with the sequence numbers N (sequence numbers 91, 2, 12 and 22) of the RTP packets dropped from the communication line and not stored in the buffer 93. The error correction unit 94 executes error correction by using the RTP packets (RTP packets with the sequence numbers 1, 3 to 10) stored in the buffer 93. It is therefore possible to recover the RTP packet with the sequence number 2 and-obtain RTP packets 202 subjected to the error correction for recovering the RTP packet with the sequence number 2. In the RTP packets 202, only the RTP packets constituted of TS packets are shown.

Although not shown, similarly, the RTP packet with the sequence number 12 is subjected to error correction by using the RTP packets with the numbers 11, and 13 to 20 including the error correction parity RTP packet with the sequence number 20, the RTP packet with the sequence number 22 is subjected to error correction by using the RTP packets with the numbers 21, and 23 to 30 including the error correction parity RTP packet with the sequence number 30, and the RTP packet with the sequence number 91 is subjected to error correction by using the RTP packets with the numbers 92 to 100 including the error correction parity RTP packet with the sequence number 100.

The error correction unit 94 supplies as the AV signal the error-corrected RTP packets 202 (sequence numbers 1 to 9) 202, to the display controller unit 72 via the TS streaming unit 95 and MPEG decoder unit 96 not shown. The display controller unit 72 controls to display the AV signal from the MPEG decoder unit 96 on the display unit 73, and the display unit 73 displays an image based upon the AV signal with error correction for the dropped RTP packet.

As described above, in the transmission/reception system shown in FIG. 12, since the rearranged RTP packets are transmitted, it is possible to recover through error correction RTP packets dropped from the communication line as many as possible.

Namely, for example, if the transmitter unit 163 transmits RTP packets 201 to the receiver unit 171 and four RTP packets are dropped from the communication line in succession, error correction cannot be made perfectly even if the error correction parity packet with the sequence number 10 is used. However, as described above, by making the transmitter unit 163 rearrange the RTP packets to be transmitted and making the receiver unit 171 rearranges the order to the original order, it becomes possible to recover, through error correction, RTP packets dropped in succession as many as possible.

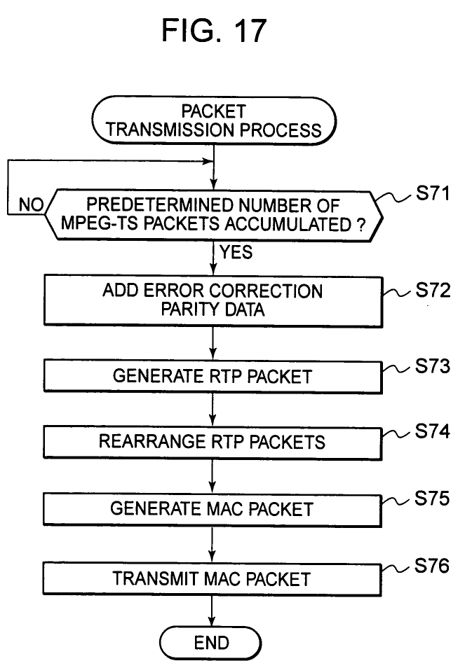

Next, with reference to the flow chart of FIG. 17, description will be made on a packet transmission process by the transmitter unit 163 of the recording/reproducing apparatus 151.

Data read from the optical disk 153 by the recording/reproducing unit 161 is converted into an AV signal of the MPEG-TS stream by the TS packetizer unit 162 and supplied to the transmitter unit 163.

At Step S71, the error correction adding unit 82 of the transmitter unit 163 stands by until a predetermined number of MPEG-TS packets are stored in the buffer 81, and if it is judged that the predetermined number of MPEG-TS packets are stored in the buffer 81, the flow proceeds to Step S72 whereat error correction parity data is added to the predetermined number of TS packets stored in the buffer 81 to thereafter proceed to Step S73. For example, in the example shown in FIG. 14, the error correction adding unit 82 adds the error correction parity data to sixty three TS packets (nine RTP packets).

At Step S73 the RTP packetizer unit 83 collects a preset number (in the case of FIG. 15, seven) of TS packets from the TS packets added with the error correction parity data and stored in the buffer 81, and adds an RTP header to the collected TS packets to generate an RTP packet to thereafter proceed to Step S74. In this case, the RTP packetizer unit 83 assigns a sequence number of the RTP header by sequentially incrementing by 1 at a time.

At Step S74 the interleaver 181 rearranges the RTP packets generated by the RTP packetizer unit 83 and stored in the buffer 81 to a predetermined order, and supplies the rearranged RTP packets to the MAC framing unit 84 to thereafter proceed to Step S75. For example, in the case of FIG. 15, the interleaver 181 rearranges the RTP packets in the unit of 10 packets.

At Step S75 the MAC framing unit 84 adds a UDP header to the RTP packet rearranged by the interleaver 181 to generate a UDP packet, adds an IP header to the generated UDP packet to generate an IP packet, adds a MAC header to the generated IP packet to generate a MAC packet, and supplies it to the wireless transmitter module 85 to thereafter proceed to Step S76.

At Step S76 the wireless transmitter module 85 transmits the MAC packet supplied from the MAC framing unit 84 to the display 152 via wireless communications of IEEE802.11 standard to thereafter terminate the packet transmission process.

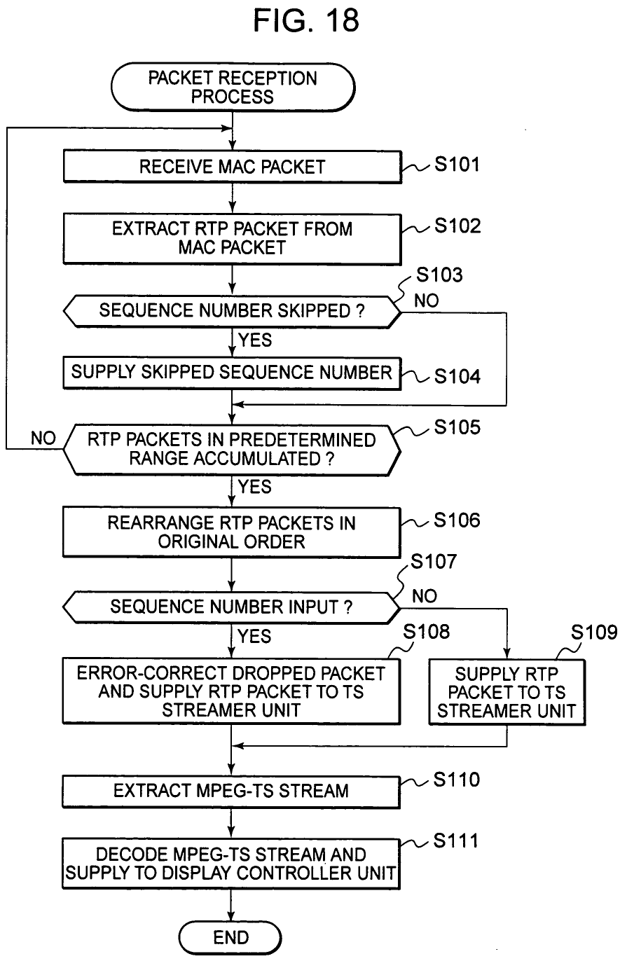

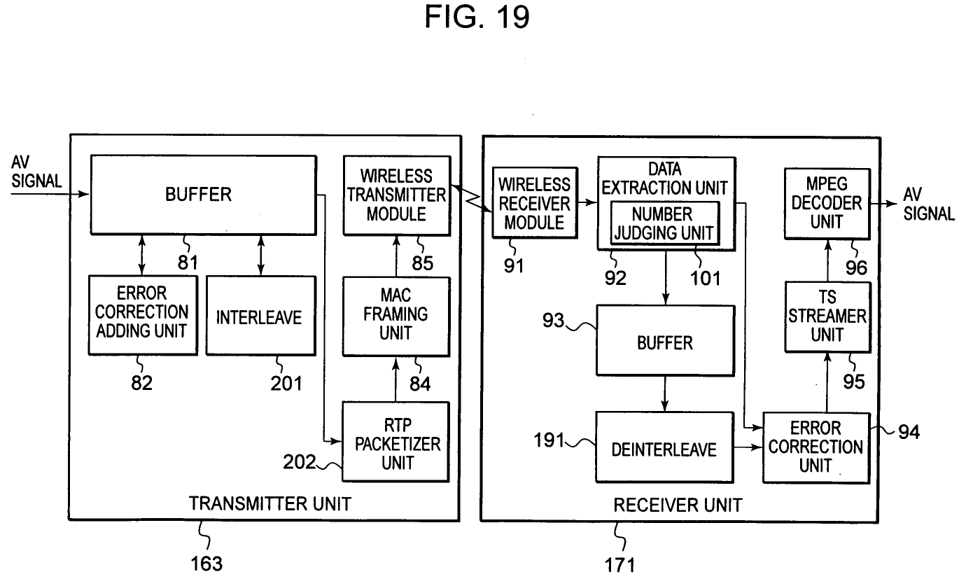

With reference to the flow chart of FIG. 18, description will be made on a packet reception process by the receiver unit 171 of the display 152 to be executed in response to the packet transmission process by the transmitter unit 163 described above.

A MAC packet is transmitted from the transmitter unit 163 of the signal receiver 151 via wireless communications of IEEE802.11 standard. At Step S101 the wireless receiver module 91 receives the MAC packet transmitted from the recording/reproducing apparatus 151, and supplies the received MAC packet to the data extraction unit 92 to thereafter proceed to Step S102.

At Step S102 the data extraction unit 92 extracts an RTP packet from the MAC packet supplied from the wireless receiver module 91, and supplies the extracted RTP packet to the buffer 93 to thereafter proceed to Step S103. At Step S103 the number judging unit 101 judges whether the sequence numbers of the RTP headers of the RTP packets extracted by the data extraction unit 92 are in the order rearranged by the interleaver 181 (i.e., whether the sequence numbers are not skipped). If it is judged that the sequence numbers of the RTP headers of the extracted RTP packets are not in the rearranged order (i.e., the sequence numbers are skipped), then the skipped sequence number is supplied to the error correction unit 94 to thereafter proceed to Step S105.

If it is judged at Step S103 that the sequence numbers of the RTP headers of the RTP packets extracted by the data extraction unit 92 are in the rearranged order (i.e., the sequence numbers are not skipped), then the process at Step S104 is skipped to proceed to Step S105.

The buffer 93 stores the rearranged RTP packets added with the error correction parity data. At Step S105 the deinterleaver 191 judges whether the RTP packets in a predetermined range (with the sequence numbers in a rearrangement range) are stored. If it is judged that the RTP packets in the predetermined range (with the sequence numbers in the rearrangement range) are not stored, the flow returns to Step S101 to repeat Step S101 and succeeding Steps. In the example of FIG. 16, the rearrangement range requires that the RTP packets up to the RTP packet with the number 100 are stored.

If it is judged that the RTP packets in the predetermined range are stored in the buffer 93, the flow proceeds to Step S106 whereat the deinterleaver 191 rearranges the RTP packets rearranged by the interleaver 181 to the original order and supplies the rearranged RTP packets to the error correction unit 94 to thereafter proceed to Step S107.

As the RTP packets are input from the deinterleaver 191, at Step S107 the error correction unit 94 judges whether the sequence number was input from the number judging unit 101. If it is judged that the sequence number was input, the flow proceeds to Step S108 whereat error correction is executed for the RTP packet with the sequence number supplied from the number judging unit 101, by using the predetermined number (in the example of FIG. 16, the RTP packets with the number 1 to the number 10) of RTP packets with the error parity data (in the example of FIG. 16, the RTP packet with the number 10), among the RTP packets rearranged by the deinterleaver 191, and supplies the error-corrected RTP packets to the TS streaming unit 95 to thereafter proceed to Step S110.

If it is judged at Step S107 that the sequence number was not input from the number judgement unit 101, the flow proceeds to Step S109 whereat the error correction unit 94 supplies the predetermined number of RTP packets rearranged by the deinterleaver 191 directly to the TS streaming unit 95 to thereafter proceed to Step S110.

At Step S110 the TS streaming unit 95 obtains MPEG-TS streams excluding the error correction parity from the RTP packets supplied from the error correction unit 94, and stores the streams in an buffer (not shown in the figure) to thereafter proceed to Step S111. At Step S111 the MPEG decoder unit 96 decodes the MPEG-TS streams stored in the buffer of the TS streaming unit 95, and supplies the decoded AV signal to the display controller unit 72 to thereafter terminate the packet reception process. The display controller unit 72 controls to display the AV signal from the MPEG decoder unit 96 on the display unit 73 so that an image based on the AV signal is displayed on the display unit 73.

As described above, the transmitter unit 163 adds error correction parity data to the TS packets to generate RTP packets and sequentially assigns the sequence number incremented by 1 at a time to each of the RTP packets added with the error correction parity data. Accordingly, the receiver unit 171 can execute error correction with ease only by confirming the sequence number.

Further, the transmitter unit 163 transmits the rearranged RTP packets added with the error correction parity data and the receiver unit 171 rearranges the received RTP packets to the original order. Errors can be corrected as many as possible for packet drops occurring in succession in a burst manner. The communication quality under the bad wireless communication conditions can therefore be improved by a simple method.

Namely, only by presetting the range of RTP packets to be subjected to error correction, the rearranging method and the like between the transmitter unit 163 and receiver unit 171, a transmission/reception system can be configured easily because it is unnecessary to newly define an error correction mechanism for the transmitter unit 163 and receiver unit 171 and to prepare special functions for the mechanism.

FIG. 19 shows another example of the transmitter unit 163 of the recording/reproducing apparatus 151 shown in FIG. 12. The transmitter unit 163 of FIG. 19 has the similar structure to that of the transmitter unit 163 previously described with FIG. 13, excepting that the interleaver 181 is changed to an interleaver 201 and that the RTP packetizer unit 83 is changed to an RTP packetizer unit 202. Namely, a different point resides only in that in the transmitter unit 163 of FIG. 13, the process by the interleaver 181 is executed after the process by the RTP packetizer unit 83, whereas in the transmitter unit 163 of FIG. 19, the process by the RTP packetizer unit 202 is executed after the interleaver 181.

The transmitter unit 163 includes a buffer 81, an error correction adding unit 82, the interleaver 201, the RTP packetizer unit 202, a MAC framing unit 84 and a wireless transmitter module 85.

In the example of FIG. 19, the interleaver 201 of the transmitter unit 163 collects a predetermined number of TS packets added with error correction parity data and stored in the buffer 81, e.g., seven TS packets, and rearranges the collected TS packets in a predetermined order (e.g., the order of TS packets shown in the example of FIG. 15).

The RTP packetizer unit 202 adds an RTP header to the seven TS packets rearranged in the predetermined order by the interleaver 201 to generate an RTP packet, and supplies the generated RTP packet to the MAC framing unit 84. In this case, the RTP packetizer unit 202 sequentially assigns the sequence numbers 1, 11, 21, . . . as in the RTP packet order shown in FIG. 15 to generate RTP packets. Namely, in the example of FIG. 19, since TS packets are rearranged before RTP packets are generated, the RTP packetizer unit 202 sequentially assigns the sequence numbers incremented by 1 at a time to the RTP packets before rearrangement.

The MAC framing unit 84 adds a UDP header to the RTP packet supplied from the RTP packetizer unit 202 to generate UDP packet, adds an IP header to the generated UDP packet to generate an IP packet, adds a MAC header to the generated IP packet, and supplies the MAC packet to the wireless transmitter module 85.

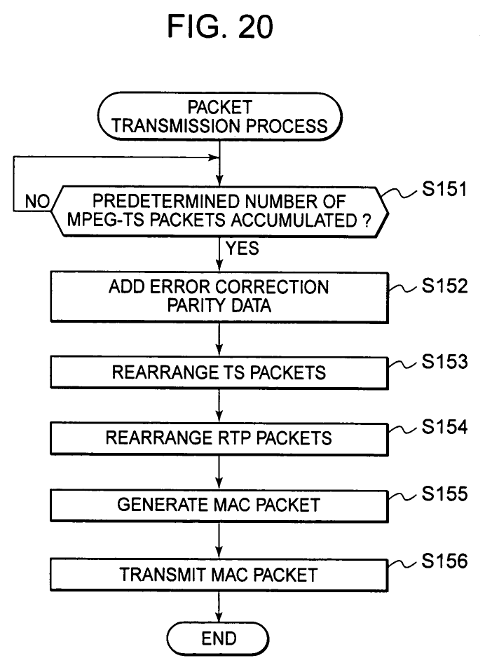

Next, with reference to the flow chart of FIG. 20, description will be made on a packet transmission process by the transmitter unit 163 of FIG. 19. Since the processes at Steps S151, S152, S155 and S156 of FIG. 20 are basically the same as the processes at Steps S71, S72, S75 and S76 of FIG. 17, the description thereof is omitted where appropriate because of duplication.

At Step S151 the error correction adding unit 82 of the transmitter unit 163 stands by until a predetermined number of MPEG-TS packets are stored in the buffer 81. If it is judged that the predetermined number of TS packets are stored in the buffer 81, the flow proceeds to Step S152 whereat error correction parity data is added to the predetermined number of TS packets stored in the buffer 81 to thereafter proceed to Step S153.

At Step S153 the interleaver 201 collects a preset number of TS packets added with the error correction parity data and stored in the buffer 81, e.g., seven TS packets, and rearranges to a predetermined order (the TS packet order shown in the example of FIG. 15) to thereafter proceed to Step S154.

At Step S154 the RTP packetizer unit 202 adds an RTP header to the seven TS packets rearranged in the predetermined order by the interleaver 201 to generate an RTP packet, and supplies the generated RTP packet to the MAC framing unit 84 to thereafter proceed to Step S155. In this case, the RTP packetizer unit 202 assigns the preset sequence numbers (as in the RTP packet order shown in FIG. 15) to RTP packets. Namely, since TS packets are rearranged before RTP packets are generated, the RTP packetizer unit 202 sequentially assigns the sequence numbers incremented by 1 at a time to the RTP packets before rearrangement.

At Step S155 the MAC framing unit 84 adds a UDP header to the RTP packet supplied from the RTP packetizer unit 202 to generate a UDP packet, adds an IP header to generate an IP packet, adds a MAC header to the generated IP packet to generate a MAC packet, and supplies the generated MAC packet to the wireless transmitter module 85 to thereafter proceed to Step S156.

At Step S156 the wireless transmitter module 85 transmits the MAC packet supplied from the MAC framing unit 84 to the display 152 via wireless communications of IEEE802.11 standard, and thereafter terminate the packet transmission process.

As described above, in the transmission/reception system of FIG. 19, if the rearrangement order, the range of RTP packets added with error correction parity data and the like are preset between the transmitter unit 163 and receiver unit 171, the order of processes in the transmitter unit 163 may be exchanged.

In the description of the example of FIG. 19, although the order of processes in the transmitter unit 163 is exchanged, the order of processes in the receiver unit 171 may be exchanged. Namely, after the order of RTP packets is rearranged to the original order by the deinterleaver 191 shown in FIG. 13, the number judging unit 101 may judge whether the sequence numbers of the RTP packets increase by 1 at a time. In this case, the number judging unit 101 is not necessary to consider the rearrangement by the interleaver 181 of FIG. 13.

Although data transmission/reception has been described by using wireless communications of IEEE802.11 standard, data transmission/reception is not limited only to IEEE802.11, but Ethernet® based on the standard of IEEE802.3 may also be used.

In the description of the embodiments of the present invention, the packet transmitter side uses the transmitter unit of the signal receiver 51 or recording/reproducing apparatus 151 and the packet reception side uses the display 52 or 152. However, the present invention is not limited only thereto, and may also applicable to an apparatus having a transmitter unit and a receiver unit having the structures described earlier.

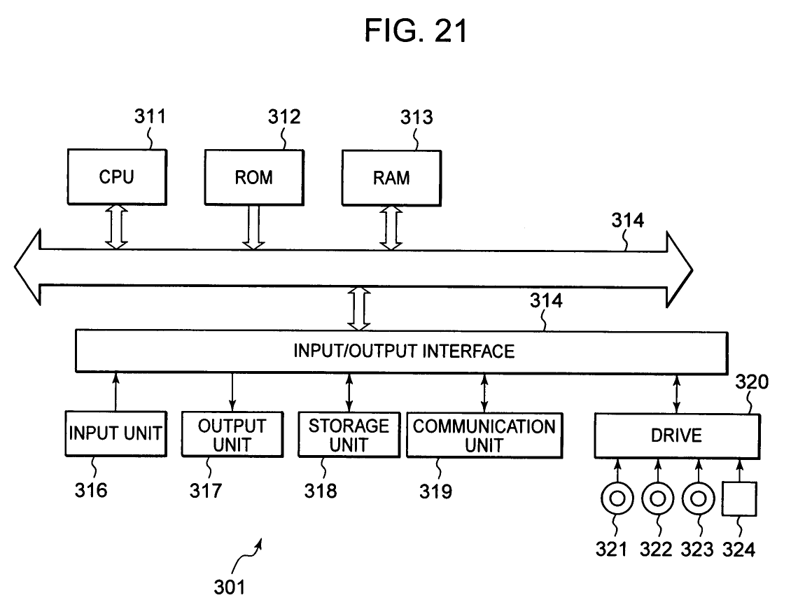

Although an above-described series of processes may be realized by hardware, they maybe realized by software. In this case, the signal receiver 51 and display 52 shown in FIG. 2 and the recording/reproducing apparatus 151 and display 152 shown in FIG. 12 are configured by an information processing apparatus 301 such as shown in FIG. 21.

Referring to FIG. 21, a CPU (Central Processing Unit) 311 executes various processes in accordance with programs stored in a ROM (Read Only Memory) 312 or programs loaded from a storage unit 318 into a RAM (Random Access Memory) 313. RAM 313 also stores data necessary for CPU 311 to execute various processes, and other data if necessary.

CPU 311, ROM 312 and RAM 313 are interconnected via a bus 314. An input/output interface 315 is also connected to the bus 314.

Connected to the input/output interface 315 are an input unit 316 constituted of a keyboard, a mouse and the like, an output unit 317 constituted of a display constituted of a CRT (Cathode Ray Tube), an LCD (Liquid Crystal Display) and the like, and a speaker, a storage unit 318 constituted of a hard disk and the like, and a communication unit 319 constituted of a modem, a terminal adapter and the like. The communication unit 319 executes a communication process via wireless communications or a network.

A drive 320 is connected if necessary to the input/output interface 315. A magnetic disk 321, an optical disk 322, a magnetic optical disk 323 or a semiconductor memory 324 or the like is loaded in the drive 320 if necessary. A computer program read from these media is installed in the storage unit 318 if necessary.

If a series of processes is executed by software, a program constituting the software is installed from a network or a recording medium in a computer assembled with dedicated hardware or a machine such as general personal computer which can execute various functions by installing various programs.

The recording medium may be not only package media constituted of a magnetic disk 321 (including a flexible disk), an optical disk 322 (including a CD-ROM (Compact Disk-Read Only Memory) and a DVD (Digital Versatile Disk)), a magnetic optical disk 323 (including an MD (Mini-Disk)™ a semiconductor memory 324 or the like, respectively recording a program and distributed to supply the program to users separately from the apparatus itself, but also ROM 312, a hard disk included in the storage unit 319 or the like, respectively storing a program to be supplied to users in the state assembled beforehand in the apparatus itself.

In this specification, Steps shown in the flow charts contain not only a process to be executed time sequentially in the order of written statements but also a process to be executed parallel or independently without being processed time sequentially.

In this specification, “a system” means the entire apparatus constituted of a plurality of apparatuses.

It should be understood by those skilled in the art that various modifications, combinations, sub-combinations and alternations may occur depending on design requirements and other factors insofar as they are within the scope of the appended claims or the equivalents thereof.

1. A transmission/reception system comprising a transmitter transmitting data and a receiver receiving the data transmitted from the transmitter, wherein:
the transmitter includes
error correction adding means for adding error correction data to each set of N number of TS (Transport Stream) packets,
RTP (Real-time Transport Protocol) packet generating means for generating an RTP packet by collecting M (N>M) number of TS packets with added error correction data by the error correction adding means and sequentially assigning a sequence number to each set of the M number of TS packets, and
transmitter means for transmitting each RTP packet generated by the RTP packet by converting the RTP packets generated by the RTP packet generating means into data transmittable to a receiver;
the receiver includes
receiver means for receiving the data from the transmitter,
packet acquiring means for acquiring the RTP packet from the data received by the receiver means,
packet judging means for judging, from the sequence number of the RTP packet acquired by the packet acquiring means, whether there is any dropped packet not received by the receiver means, and
packet correcting means for correcting the dropped packet by using the RTP packets acquired by the packet acquiring means, if the packet judging means judges that there is a dropped packet not received.

2. The transmission/reception system according to claim 1, wherein:
the transmitter further includes interleaver means for rearranging an order of the RTP packets generated by the RTP packet generating means to a predetermined order, before the RTP packets are transmitted by the transmitter means; and
the receiver further includes deinterleaver means for rearranging the order of the RTP packets acquired by the packet acquiring means to an original order before being rearranged to the predetermined order by the interleaver means.

3. A transmitter transmitting data to a receiver, the transmitter comprising:
error correction adding means for adding error correction data to each set of N number of TS (Transport Stream) packets;
RTP (Real-time Transport Protocol) packet generating means for generating an RTP packet by collecting M (N>M) number of TS packets added with the error correction data by the error correction adding means and sequentially assigning a sequence number to each set of M TS packets; and
transmitter means for transmitting each RTP packet generated by the RTP packet generating means by converting the RTP packets into data transmittable to a receiver.

4. The transmitter according to claim 3, further comprising:
interleaver means for rearranging an order of the RTP packets generated by the RTP packet generating means to a predetermined order, before the RTP packets are transmitted by the transmitter means.

5. A transmitting method of a transmitter operable to transmit data to a receiver, the method comprising:
an error correction adding step of adding error correction data to each set of N number of TS (Transport Stream) packets;
an RTP (Real-time Transport Protocol) packet generating step of generating an RTP packet by collecting M (N>M) number of TS packets added with the error correction data by the error correction adding step and sequentially assigning a sequence number to each set of M TS packets; and
a transmitting step of transmitting each RTP packet generated by the RTP packet generating step by converting the RTP packets into data transmittable to a receiver.

6. A recording medium in which a program causes a computer to perform a process of transmitting data to a receiver is stored, the program comprising:
an error correction adding step of adding error correction data to each set of N number of TS (Transport Stream) packets;
an RTP (Real-time Transport Protocol) packet generating step of generating an RTP packet by collecting M (N>M) number of TS packets added with the error correction data by the error correction adding step and sequentially assigning a sequence number to each set of M TS packets; and
a transmitting step of transmitting each RTP packet generated by the RTP packet generating step by converting the RTP packets into data transmittable to a receiver.

7. A program causing a computer to perform a process of transmitting data to a receiver, the program comprising:
an error correction adding step of adding error correction data to each set of N number of TS (Transport Stream) packets;
an RTP (Real-time Transport Protocol) packet generating step of generating an RTP packet by collecting M (N>M) number of TS packets added with the error correction data by the error correction adding step and sequentially assigning a sequence number to each set of M TS packets; and
a transmitting step of transmitting each RTP packet generated by the RTP packet generating step by converting the RTP packets into data transmittable to a receiver.

8. A receiver receiving data from a transmitter, the receiver comprising:
receiver means for receiving data from the transmitter, the data including an RTP (Real-time Transport Protocol) packet generated by collecting M number of TS packets added with the error correction data for N (N>M) number of TS (Transport Stream) packets and sequentially assigning a sequence number to each set of M number of TS packets;
packet acquiring means for acquiring the RTP packet from the data received by the receiver means;
packet judging means for judging, from the sequence number of the RTP packet acquired by the packet acquiring means, whether there is any dropped packet not received by the receiver means; and
packet correcting means for correcting the dropped packet by using the RTP packets acquired by the packet acquiring means, if the packet judging means judges that there is a dropped packet not received.

9. The receiver according to claim 8,
wherein the RTP packets in the data received by the receiver means are rearranged to a predetermined order by the transmitter,
the receiver further comprising deinterleaver means for rearranges the order of the RTP packets acquired by the packet acquiring means to an original order before being rearranged to the predetermined order by the transmitter.

10. A receiving method of receiving data from a transmitter, the receiving method comprising:
a receiving step of receiving data from the transmitter, the data including an RTP (Real-time Transport Protocol) packet generated by collecting M number of TS packets added with the error correction data for N (N>M) number of TS (Transport Stream) packets and sequentially assigning a sequence number to each set of M number of TS packets;
a packet acquiring step of acquiring the RTP packet from the data received by the receiving step;
a packet judging step of judging, from the sequence number of the RTP packet acquired by the packet acquiring step, whether there is any dropped packet not received by the receiver step; and
a packet correcting step of correcting the dropped packet by using the RTP packets acquired by the packet acquiring step, if the packet judging step judges that there is a dropped packet not received.

11. A recording medium in which a program causes a computer to perform a process of receiving data from a transmitter is stored, the program comprising:
a receiving step of receiving data from the transmitter, the data including an RTP (Real-time Transport Protocol) packet generated by collecting M number of TS packets added with the error correction data for N(N>M) number of TS (Transport Stream) packets and sequentially assigning a sequence number to each set of M number of TS packets;
a packet acquiring step of acquiring the RTP packet from the data received by the receiving step;
a packet judging step of judging, from the sequence number of the RTP packet acquired by the packet acquiring step, whether there is any dropped packet not received by the receiver step; and
a packet correcting step of correcting the dropped packet by using the RTP packets acquired by the packet acquiring step, if the packet judging step judges that there is a dropped packet not received.

12. A program causing a computer to perform a process of receiving data from a transmitter, the program comprising:
a receiving step of receiving data from a transmitter, the data including an RTP (Real-time Transport Protocol) packet generated by collecting M number of TS packets added with the error correction data for N number of (N>M) TS (Transport Stream) packets and sequentially assigning a sequence number to each set of M number of TS packets;
a packet acquiring step of acquiring the RTP packet from the data received by the receiving step;
a packet judging step of judging, from the sequence number of the RTP packet acquired by the packet acquiring step, whether there is any dropped packet not received by the receiver step; and
a packet correcting step of correcting the dropped packet by using the RTP packets acquired by the packet acquiring step, if the packet judging step judges that there is a dropped packet not received.

13. A transmission/reception system comprising a transmitter transmitting data and a receiver receiving the data transmitted from the transmitter, wherein:
the transmitter includes
an error correction adding unit operable to add error correction data to each set of N number of TS (Transport Stream) packets,
a RTP (Real-time Transport Protocol) packet generating unit operable to generate an RTP packet by collecting M (N>M) number of TS packets with added error correction data by the error correction adding unit and sequentially assigning a sequence number to each set of the M number of TS packets, and
a transmitter unit operable to transmit each RTP packet generated by the RTP packet generator by converting the RTP packets into data transmittable to the receiver;
the receiver includes
a receiver unit operable to receive the data from the transmitter,
a packet acquiring unit operable to acquire the RTP packet from the data received by the receiver unit,
a packet judging unit operable to judge, from the sequence number of the RTP packet acquired by the packet acquiring unit, whether there is any dropped packet not received by the receiver unit, and
a packet correcting unit operable to correct the dropped packet by using the RTP packets acquired by the packet acquiring unit, if the packet judging unit judges that there is a dropped packet not received.

14. A transmitter transmitting data to a receiver, the transmitter comprising:
an error correction adding unit operable to add error correction data to each set of N number of TS (Transport Stream) packets;
a RTP (Real-time Transport Protocol) packet generating unit operable to generate an RTP packet by collecting M (N>M) number of TS packets added with the error correction data by the error correction adding unit and sequentially assigning a sequence number to each set of M TS packets; and
a transmitter unit operable to transmit each RTP packet generated by the RTP packet generating unit by converting the RTP packets into data transmittable to a receiver.

15. A receiver receiving data from a transmitter, the receiver comprising:
a receiver unit operable to receive data from the transmitter, the data including an RTP (Real-time Transport Protocol) packet generated by collecting M number of TS packets added with the error correction data for N (N>M) number of TS (Transport Stream) packets and sequentially assigning a sequence number to each set of M number of TS packets;
a packet acquiring unit operable to acquire the RTP packet from the data received by the receiver unit;
a packet judging unit operable to judge, from the sequence number of the RTP packet acquired by the packet acquiring unit, whether there is any dropped packet not received by the receiver unit; and
a packet correcting unit operable to correct the dropped packet by using the RTP packets acquired by the packet acquiring unit, if the packet judging unit judges that there is a dropped packet not received.
